(19) United States
(12) Patent Application Publication
(10) Pub. No.: US 2025/0232996 A1
(43) Pub. Date: Jul. 17, 2025

(54) CONVEYANCE APPARATUS, CONVEYANCE METHOD, AND SEMICONDUCTOR APPARATUS MANUFACTURING METHOD

(71) Applicant: JSW Aktina System Co., Ltd., Yokohama-shi, Kanagawa (JP)

(72) Inventors: Teruaki SHIMOJI, Yokohama-shi, Kanagawa (JP); Ryo SHIMIZU, Yokohama-shi, Kanagawa (JP); Daisuke ITO, Yokohama-shi, Kanagawa (JP); Takahiro FUJI, Yokohama-shi, Kanagawa (JP); Yoshihiro YAMAGUCHI, Yokohama-shi, Kanagawa (JP)

(73) Assignee: JSW Aktina System Co., Ltd., Yokohama-shi, Kanagawa (JP)

(21) Appl. No.: 18/853,843

(22) PCT Filed: Apr. 14, 2022
(86) PCT No.: PCT/JP2022/017852

§ 371 Date: Oct. 3, 2024

(51) Int. Cl. H01L 21/677; H01L 21/66; H01L 21/67; H01L 21/68

(52) U.S. Cl. CPC H01L 21/6779; H01L 21/67098; H01L 21/681; H01L 22/10

(57) ABSTRACT

A conveyance apparatus according to the present embodiment is a conveyance apparatus configured to convey a substrate to irradiate the substrate with a linear laser beam and includes: a levitation unit including a plurality of levitation unit cells arranged with gaps in between, the levitation unit being configured to levitate the substrate over an upper surface of the levitation unit; a holding mechanism configured to hold the substrate over the levitation unit; a moving mechanism configured to move the holding mechanism in a conveyance direction tilted from a line direction of the laser beam; a base supporting the levitation unit cells; and a displacement meter configured to detect height of the substrate provided in a gap directly below an irradiation region of the laser beam.

### TECHNICAL FIELD

The present invention relates to a conveyance apparatus, a conveyance method, and a semiconductor apparatus manufacturing method.

### BACKGROUND ART

A laser anneal apparatus for forming a polycrystalline silicon thin film is disclosed in Patent Literature 1. In Patent Literature 1, a projection lens focuses a laser beam onto a substrate so that the laser beam forms a linear irradiation region. Accordingly, an amorphous silicon film is crystallized into a poly-silicon film.

In Patent Literature 1, the conveyance unit conveys the substrate in a state in which a levitation unit levitates the substrate. Further, a loading position and an unloading position of the substrate are the same at the levitation unit. The conveyance unit conveys the substrate along each side of the levitation unit. The substrate circulates over the levitation unit twice, and accordingly, substantially the entire surface of the substrate is irradiated with a laser beam.

### CITATION LIST

### Patent Literature

Patent Literature 1: Japanese Unexamined Patent Application Publication No. 2018-64048

### SUMMARY OF INVENTION

In such a conveyance apparatus of a laser irradiation apparatus, a substrate is desired to be conveyed appropriately so that a laser irradiation process is stably executed at high speed. For example, it is desired to levitate the substrate at high levitation accuracy.

Other problems and novel features will become apparent from the description and accompanying drawings of the present specification.

According to an embodiment, a conveyance apparatus is a conveyance apparatus configured to convey a substrate to irradiate the substrate with a linear laser beam and includes: a levitation unit including a plurality of levitation unit cells arranged with gaps in between, the levitation unit being configured to levitate the substrate over an upper surface of the levitation unit; a holding mechanism configured to hold the substrate over the levitation unit; a moving mechanism configured to move the holding mechanism in a conveyance direction tilted from a line direction of the laser beam when viewed from top to change an irradiation position of the laser beam on the substrate; a base supporting the levitation unit cells; and a displacement meter configured to detect height of the substrate provided in a gap directly below an irradiation region of the laser beam.

According to an embodiment, a conveyance apparatus is a conveyance apparatus configured to convey a substrate to irradiate the substrate with a linear laser beam and includes: a levitation unit including a plurality of levitation unit cells arranged with gaps in between, the levitation unit being configured to levitate the substrate over an upper surface of the levitation unit; a holding mechanism configured to hold the substrate over the levitation unit; a moving mechanism configured to move the holding mechanism in a conveyance direction tilted from a line direction of the laser beam when viewed from top to change an irradiation position of the laser beam on the substrate; a base supporting the levitation unit cells; and a cooling unit provided at the base, disposed in the gap in the irradiation region of the laser beam, and including a cooling path disposed in the line direction of the laser beam.

According to an embodiment, a conveyance apparatus is a conveyance apparatus configured to convey a substrate to irradiate the substrate with a linear laser beam and includes: a levitation unit including a plurality of levitation unit cells arranged with gaps in between, the levitation unit being configured to levitate the substrate over an upper surface of the levitation unit; a holding mechanism configured to hold the substrate over the levitation unit; a moving mechanism configured to move the holding mechanism in a conveyance direction tilted from a line direction of the laser beam when viewed from top to change an irradiation position of the laser beam on the substrate; a tray provided with a through-hole and supporting the moving mechanism; a chamber housing the levitation unit, the holding mechanism, the moving mechanism, and the tray; and an exhaust pipe including an exhaust port disposed below the tray, the exhaust pipe being connected to outside of the chamber.

According to an embodiment, a conveyance method is a conveyance method of conveying a substrate by using a conveyance apparatus to irradiate the substrate with a linear laser beam, in which: the conveyance apparatus includes a levitation unit including a plurality of levitation unit cells arranged with gaps in between, the levitation unit being configured to levitate the substrate over an upper surface of the levitation unit, a base supporting the levitation unit cells, and a displacement meter configured to detect height of the substrate provided in a gap directly below an irradiation region of the laser beam; and the conveyance method includes (A1) step of holding the substrate by a holding mechanism, (A2) step of conveying the substrate over the levitation unit by moving the holding mechanism by a moving mechanism, (A3) and step of measuring, by the displacement meter, levitation height of the substrate being conveyed.

According to an embodiment, a conveyance method is a conveyance method of conveying a substrate by using a conveyance apparatus to irradiate the substrate with a linear laser beam, in which: the conveyance apparatus includes a levitation unit including a plurality of levitation unit cells arranged with gaps in between, the levitation unit being configured to levitate the substrate over an upper surface of the levitation unit, a base supporting the levitation unit cells, and a cooling unit provided at the base, disposed in the gap in the irradiation region of the laser beam, and including a cooling path disposed in the line direction of the laser beam; and the conveyance method includes (B1) step of holding the substrate by a holding mechanism, and (B2) step of conveying the substrate over the levitation unit by moving the holding mechanism by a moving mechanism.

According to an embodiment, a conveyance method is a conveyance method of conveying a substrate by using a conveyance apparatus to irradiate the substrate with a linear laser beam, in which: the conveyance apparatus includes a levitation unit including a plurality of levitation unit cells arranged with gaps in between, the levitation unit being configured to levitate the substrate over an upper surface of the levitation unit, a holding mechanism configured to hold the substrate over the levitation unit, a moving mechanism configured to move the holding mechanism in a conveyance direction tilted from a line direction of the laser beam when viewed from top to change an irradiation position of the laser beam on the substrate, a tray provided with a through-hole and supporting the moving mechanism, a chamber housing the levitation unit, the holding mechanism, the moving mechanism, and the tray, and an exhaust pipe including an exhaust port disposed below the tray, the exhaust pipe being connected to outside of the chamber; and the conveyance method includes (C1) step of holding the substrate by the holding mechanism, and (C2) step of conveying the substrate over the levitation unit by moving the holding mechanism by the moving mechanism.

According to an embodiment, a semiconductor apparatus manufacturing method includes (sa1) step of forming an amorphous film on a substrate, and (sa2) step of annealing the amorphous film by irradiating the substrate with a linear laser beam while conveying the substrate by using a conveyance apparatus so that the amorphous film is crystallized to form a crystallized film, in which the conveyance apparatus includes a levitation unit including a plurality of levitation unit cells arranged with gaps in between, the levitation unit being configured to levitate the substrate over an upper surface of the levitation unit, a holding mechanism configured to hold the substrate over the levitation unit, a moving mechanism configured to move the holding mechanism in a conveyance direction tilted from a line direction of the laser beam when viewed from top to change an irradiation position of the laser beam on the substrate, a base supporting the levitation unit cells, and a displacement meter configured to detect height of the substrate provided in a gap directly below an irradiation region of the laser beam.

According to an embodiment, a semiconductor apparatus manufacturing method includes (sb1) step of forming an amorphous film on a substrate, and (sb2) step of annealing the amorphous film by irradiating the substrate with a linear laser beam while conveying the substrate by using a conveyance apparatus so that the amorphous film is crystallized to form a crystallized film, in which the conveyance apparatus is a conveyance apparatus configured to convey a substrate to irradiate the substrate with a linear laser beam and includes a levitation unit including a plurality of levitation unit cells arranged with gaps in between, the levitation unit being configured to levitate the substrate over an upper surface of the levitation unit, a holding mechanism configured to hold the substrate over the levitation unit, a moving mechanism configured to move the holding mechanism in a conveyance direction tilted from a line direction of the laser beam when viewed from top to change an irradiation position of the laser beam on the substrate, a base supporting the levitation unit cells, and a cooling unit provided at the base, disposed in the gap in the irradiation region of the laser beam, and including a cooling path disposed in the line direction of the laser beam.

According to an embodiment, a semiconductor apparatus manufacturing method includes (sc1) step of forming an amorphous film on a substrate, and (sc2) step of annealing the amorphous film by irradiating the substrate with a linear laser beam while conveying the substrate by using a conveyance apparatus so that the amorphous film is crystallized to form a crystallized film, in which the conveyance apparatus includes a levitation unit including a plurality of levitation unit cells arranged with gaps in between, the levitation unit being configured to levitate the substrate over an upper surface of the levitation unit, a holding mechanism configured to hold the substrate over the levitation unit, a moving mechanism configured to move the holding mechanism in a conveyance direction tilted from a line direction of the laser beam when viewed from top to change an irradiation position of the laser beam on the substrate, a tray provided with a through-hole and supporting the moving mechanism, a chamber housing the levitation unit, the holding mechanism, the moving mechanism, the tray, and an exhaust pipe including an exhaust port disposed below the tray, the exhaust pipe being connected to outside of the chamber.

According to an embodiment, substrate conveyance suitable for a laser irradiation process can be achieved.

### BRIEF DESCRIPTION OF DRAWINGS

FIG. 1 is a top view schematically illustrating the configuration of a conveyance apparatus used for a laser irradiation apparatus;

FIG. 2 is a side cross-sectional view schematically illustrating the laser irradiation apparatus;

FIG. 3 is a schematic diagram for description of the configuration of a levitation unit;

FIG. 4 is a top view schematically illustrating a detailed configuration of the conveyance apparatus;

FIG. 5 is a top view for description of the process of conveyance by the conveyance apparatus;

FIG. 6 is a top view for description of the process of conveyance by the conveyance apparatus;

FIG. 7 is a top view for description of the process of conveyance by the conveyance apparatus;

FIG. 8 is a top view for description of the process of conveyance by the conveyance apparatus;

FIG. 9 is a top view for description of the process of conveyance by the conveyance apparatus;

FIG. 10 is a top view for description of the process of conveyance by the conveyance apparatus;

FIG. 11 is a top view for description of the process of conveyance by the conveyance apparatus;

FIG. 12 is a top view for description of the process of conveyance by the conveyance apparatus;

FIG. 13 is a top view for description of disposition of displacement meters in an irradiation region;

FIG. 14 is a side cross-sectional view for description of disposition of a displacement meter in the irradiation region;

FIG. 15 is a side cross-sectional view for description of a cooling mechanism provided at a base;

FIG. 16 is a perspective view for description of the base including the displacement meters and the cooling mechanism;

FIG. 17 is a top view illustrating the configuration of the base including the displacement meters and the cooling mechanism;

FIG. 18 is a perspective view illustrating only the configuration of the base including the displacement meters and the cooling mechanism;

FIG. 19 is a top view schematically illustrating conveyance units configured to convey a substrate in an X direction and its surrounding components;

FIG. 20 is a side view schematically illustrating the configuration of a conveyance unit and an exhaust mechanism;

FIG. 21 is a top view schematically illustrating the configuration of a tray;

FIG. 22 is a side view for description of upward-downward operation of a holding mechanism;

FIG. 23 is a side view for description of upward-downward operation of the holding mechanism;

FIG. 24 is a side view for description of the holding mechanism and its upward-downward mechanism;

FIG. 25 is a cross-sectional view illustrating the configuration of an organic light-emitting diode display in a simplified manner;

FIG. 26 is a process cross-sectional view illustrating a semiconductor apparatus manufacturing method according to the present embodiment; and

FIG. 27 is a process cross-sectional view illustrating the semiconductor apparatus manufacturing method according to the present embodiment.

### DESCRIPTION OF EMBODIMENTS

A conveyance apparatus according to the present embodiment is used for a laser irradiation apparatus such as a laser anneal apparatus. The laser anneal apparatus is, for example, an excimer laser anneal (ELA) apparatus that forms a low temperature poly-silicon (LTPS) film. A conveyance apparatus, a laser irradiation apparatus, a method, and a manufacturing method according to the present embodiment will be described below with reference to the accompanying drawings.

### Embodiment 1

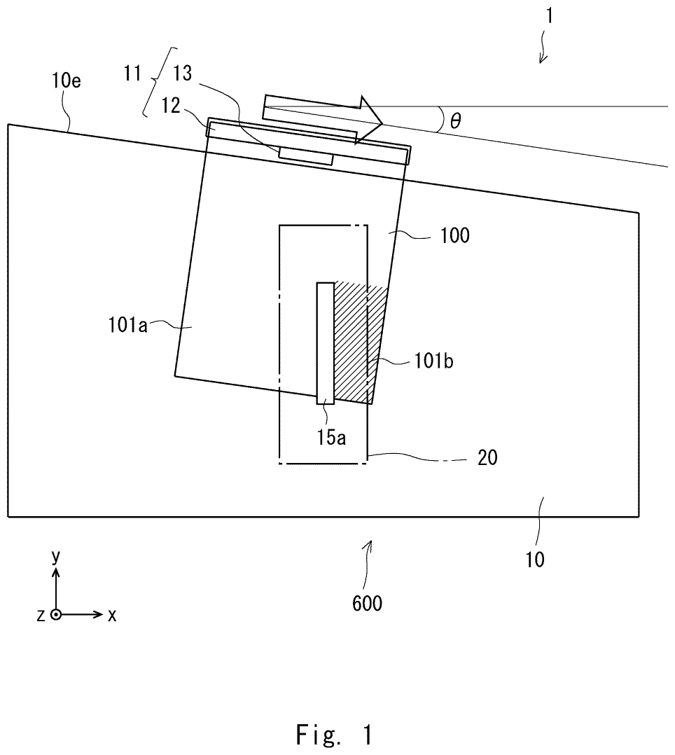

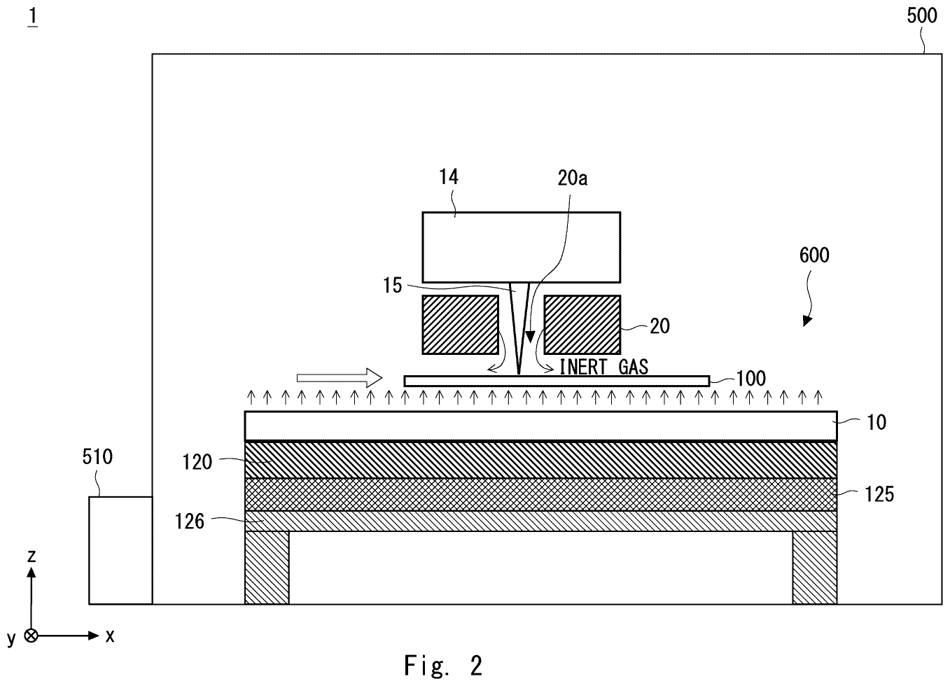

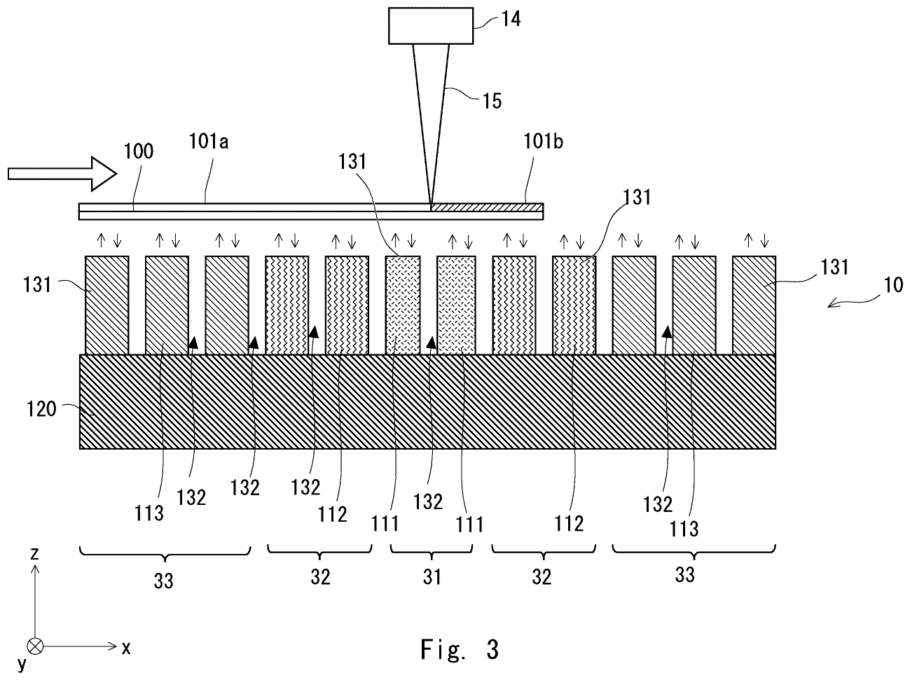

Basic configurations of the conveyance apparatus and the laser irradiation apparatus according to the present embodiment will be described below with reference to FIGS. 1 to 3. FIG. 1 is a top view schematically illustrating a basic configuration of a laser irradiation apparatus 1. FIG. 2 is a side cross-sectional view schematically illustrating the configuration of the laser irradiation apparatus 1. FIG. 3 is a side cross-sectional view schematically illustrating the configuration of an irradiation region irradiated with a laser beam and its vicinity.

Note that FIGS. 1 to 3 are conceptual diagrams illustrating only the basic configurations of the conveyance apparatus and the laser irradiation apparatus, and some components are omitted. For example, a conveyance apparatus 600 is illustrated in a simplified manner in FIG. 1. Specifically, a laser irradiation unit 14, a precise levitation region 31, a semi-precise levitation region 32, a rough levitation region 33, a precise levitation unit 111, a semi-precise levitation unit 112, and a rough levitation unit 113 are omitted in FIG. 1.

Note that, in diagrams described below, an xyz three-dimensional orthogonal coordinate system is illustrated as appropriate for simplification of explanation. The z direction is the vertical direction, and the y direction is a line direction along a linear irradiation region 15a. The x direction is a direction orthogonal to the z direction and the y direction. Accordingly, the y direction is the longitudinal direction of the linear irradiation region 15a, and the x direction is a transverse direction orthogonal to the longitudinal direction.

As illustrated in FIGS. 1 and 2, the laser irradiation apparatus 1 includes a levitation unit 10, a conveyance unit 11, and the laser irradiation unit 14. The levitation unit 10, the conveyance unit 11, and the laser irradiation unit 14 constitute a conveyance apparatus 600. The conveyance apparatus 600 may further include a base 120, a reference plate 125, a mount 126, a seal box 20, a chamber 500, and an exhaust unit 510 as illustrated in FIG. 2.

As illustrated in FIG. 2, the levitation unit 10 is configured to eject gas from a surface of the levitation unit 10. The levitation unit 10 levitates a substrate 100 over its upper surface. The substrate 100 is levitated as gas ejected from the surface of the levitation unit 10 is blown to a lower surface of the substrate 100. The substrate 100 is, for example, a glass substrate. When the substrate 100 is conveyed, the levitation unit 10 adjusts the amount of levitation so that the substrate 100 does not contact another mechanism (not illustrated) disposed on the upper side of the substrate 100.

As illustrated in FIG. 3, the levitation unit 10 is mainly divided into the precise levitation region 31, the semi-precise levitation region 32, and the rough levitation region 33. The precise levitation region 31 is a region including the irradiation region 15a of a laser beam 15. In other words, the precise levitation region 31 is a region that overlaps the focal point (irradiation region 15a) of the laser beam in an xy plan view. The precise levitation region 31 is a region larger than the irradiation region 15a.

The semi-precise levitation region 32 is a region adjacent to the precise levitation region 31. The semi-precise levitation region 32 is disposed on both sides of the precise levitation region 31 in the x direction. Each semi-precise levitation region 32 is a region larger than the precise levitation region 31.

The rough levitation region 33 is a region adjacent to one of the semi-precise levitation regions 32. Specifically, the semi-precise levitation region 32 is disposed between the rough levitation region 33 and the precise levitation region 31. The rough levitation region 33 is disposed on both sides of the precise levitation region 31 in the X direction. In other words, the rough levitation regions 33 are disposed separately on the +x side and the −x side of the semi-precise levitation regions 32. The semi-precise levitation regions 32 and the rough levitation regions 33 are regions that do not overlap the focal point (irradiation region 15a) of the laser beam in an xy plan view.

As illustrated in FIG. 3, the levitation unit 10 includes a plurality of levitation unit cells 131. Levitation unit cells 131 provided in the precise levitation region 31 are referred to as precise levitation units 111. Levitation unit cells 131 provided in the semi-precise levitation regions 32 are referred to as semi-precise levitation units 112. Levitation unit cells 131 provided in the rough levitation regions 33 are referred to as rough levitation units 113. Note that although a gap 132 is provided between each pair of levitation unit cells 131 in FIG. 3, no gaps 132 may be provided for some of the levitation unit cells 131. In other words, some levitation unit cells 131 may be in contact with an adjacent levitation unit cell 131.

The precise levitation unit 111, the semi-precise levitation unit 112, and the rough levitation unit 113 each eject gas (for example, air) upward. The gas ejected from the precise levitation unit 111, the semi-precise levitation unit 112, and the rough levitation unit 113 may be inert gas such as nitrogen gas. The substrate 100 is levitated as the gas blows onto the lower surface of the substrate 100. Accordingly, the levitation unit 10 and the substrate 100 become a non-contact state. In addition, the precise levitation unit 111 and the semi-precise levitation unit 112 suck gas existing between the substrate 100 and the levitation unit 10. The rough levitation unit 113 as well as the semi-precise levitation unit 112 are configured to be able to suck gas.

For example, a gas supply source (not illustrated) for supplying gas is connected to the precise levitation unit 111, the semi-precise levitation unit 112, and the rough levitation unit 113. In addition, a vacuum generation source (not illustrated) for sucking gas is connected to the precise levitation unit 111, the semi-precise levitation unit 112, and the rough levitation unit 113. The gas supply source is a compressor, a gas tank, or the like and supplies compressed gas. The vacuum generation source is a vacuum pump, an ejector, or the like.

The precise levitation unit 111 has a higher accuracy of levitation amount than the semi-precise levitation unit 112 and the rough levitation unit 113. The semi-precise levitation unit 112 has a higher accuracy of levitation amount than the rough levitation unit 113. The substrate 100 is irradiated with a laser beam in the precise levitation region 31 having the highest accuracy of levitation amount. For example, the semi-precise levitation unit 112 is configured to levitate the substrate 100 at accuracy between accuracy when the precise levitation unit 111 levitates the substrate 100 and accuracy when the rough levitation unit 113 levitates the substrate 100.

For example, high accuracy is requested for the amount of levitation of the substrate 100 in the irradiation region 15a and the precise levitation region 31 around the irradiation region 15a. Thus, the precise levitation unit 111 capable of controlling the amount of levitation at high accuracy is used. The precise levitation unit 111 is a precise levitation unit formed of a porous body such as ceramic. Porous carbon, porous alumina ceramic, porous SiC ceramic, or the like can be used as the porous body.

The precise levitation unit 111 ejects gas upward. The precise levitation unit 111 may be provided with suction holes for sucking gas. The porous body is fabricated with suction holes reaching the upper surface at predetermined intervals. The suction holes are minute holes and form negative pressure between the substrate 100 and the precise levitation unit. The porous body ejects gas from substantially the entire surface except for the suction holes. An ejection surface that forms positive pressure is formed at substantially the entire surface except for the suction holes.

The semi-precise levitation unit 112 and the rough levitation unit 113 are formed of a metallic material. For example, the semi-precise levitation unit 112 and the rough levitation unit 113 are formed of a metal block having a hollow part. In addition, a plurality of ejection holes from the hollow part to the upper surface of the metal block are formed. The metal block may be additionally provided with suction holes that suck gas. Note that any one of the semi-precise levitation unit 112 and the rough levitation unit 113 may be omitted.

The rough levitation unit 113, the semi-precise levitation unit 112, and the precise levitation unit 111 are also collectively referred to as a levitation unit cell 131. A plurality of rough levitation units 113 are provided as levitation unit cells 131 in each rough levitation region 33. A plurality of semi-precise levitation units 112 are provided as levitation unit cells 131 in each semi-precise levitation region 32. A plurality of precise levitation units 111 are provided as levitation unit cells 131 in the precise levitation region 31. The levitation unit cells 131 are arranged with gaps 132 in between.

The levitation unit cells 131 are fixed to the base 120. In other words, the base 120 supports the levitation unit cells 131. The base 120 is fixed on the reference plate 125. The reference plate 125 is fixed on the mount 126. The mount 126 supports the reference plate 125. The mount 126 is fixed to a floor or the like.

A base 120 is, for example, a metal plate made of aluminum or made of aluminum alloy. The precise levitation units 111, the semi-precise levitation units 112, and the rough levitation units 113 are fixed to the base 120 by, for example, bolts. The base 120 supports the precise levitation units 111, the semi-precise levitation units 112, and the rough levitation units 113 as the levitation unit cells 131. The upper surfaces of the precise levitation units 111, the semi-precise levitation units 112, and the rough levitation units 113 are at the same height in effect. In other words, the upper surface (levitation surface) of the levitation unit 10 is flat in effect. The surface of the base 120 may be provided with polishing fabrication or the like to have a predetermined flatness. In addition, an internal space (not illustrated) serving as a flow path for ejecting or sucking gas may be provided inside the base 120. The levitation unit cells 131 may suck or eject gas through the internal space of the base 120.

Note that although the base 120 is integrally formed in FIG. 3, the base 120 may be formed of a plurality of divisions. In other words, the reference plate 125 may support a plurality of bases 120. The configuration of the base 120 will be described later.

The material of the reference plate 125 contains a stone material such as granite as a primary component. The reference plate 125 is a reference plate having an upper surface that can be highly accurately fabricated with flatness and can maintain flatness without much deflection during laser processing. Note that the material of the reference plate 125 does not necessarily need to contain granite and may contain a stone material other than granite as a primary component. Leveling of the mount 126 may be performed when the reference plate 125 is attached to the mount 126. The reference plate 125 may be provided only in the precise levitation region 31 for which high levitation accuracy is requested. In other words, the reference plate 125 may be only provided directly below the precise levitation units 111. The rough levitation regions 33 and the semi-precise levitation regions 32 may be disposed on a metal stage or the mount 126.

The irradiation region 15a is positioned between levitation unit cells 131 when viewed from top. Accordingly, a gap 132 is disposed directly below the irradiation region 15a. In other words, no levitation unit cell 131 exists directly below the irradiation region 15a. Thus, it is possible to prevent heating of a levitation unit cell 131 by laser irradiation. In addition, the base 120 may include a cooling unit to be described later.

The seal box 20 is disposed directly above the irradiation region 15a. The seal box 20 is locally provided to cover the irradiation region 15a when viewed from top. The seal box 20 is provided with a gas introduction port (not illustrated) through which inert gas such as nitrogen gas is introduced into the seal box 20. The gas introduced into the seal box 20 is discharged through an opening 20a at a lower surface of the seal box 20. The opening 20a through which the inert gas is discharged is positioned directly above the irradiation region 15a of the laser beam 15. Accordingly, it is possible to prevent chemical reaction such as oxidation of a film of the substrate 100 due to irradiation with the laser beam 15. Note that the seal box 20 may be provided with, for example, a window through which the laser beam 15 transmits.

The chamber 500 houses the constituent components provided in the conveyance apparatus 600. Specifically, the laser irradiation unit 14, the levitation unit 10, and the like are disposed in a space surrounded by the chamber 500. In addition, the exhaust unit 510 is provided outside the chamber 500. The exhaust unit 510 exhausts gas in the space inside the chamber 500. With the exhaust unit 510, it is possible to control airflow in the space inside the chamber 500.

The conveyance unit 11 illustrated in FIG. 1 conveys the substrate 100 being levitated in a conveyance direction. The conveyance unit 11 includes a holding mechanism 12 and a moving mechanism 13. The holding mechanism 12 holds the substrate 100. For example, the holding mechanism 12 may be constructed by using a vacuum adsorption mechanism. The vacuum adsorption mechanism is formed of a metallic material such as aluminum alloy. Alternatively, the holding mechanism 12 may be formed of a resin material such as a polyetheretherketone (PEEK) material. Adsorption grooves, adsorption holes, or the like are formed at the upper surface of the holding mechanism 12. The holding mechanism 12 may be formed of a porous material.

The holding mechanism 12 (vacuum adsorption mechanism) is connected to an exhaust port (not illustrated), and the exhaust port is connected to an ejector, a vacuum pump, or the like. Accordingly, negative pressure for sucking gas acts on the holding mechanism 12, and thus the substrate 100 can be held by using the holding mechanism 12.

The holding mechanism 12 includes an upward-downward movement mechanism (not illustrated) for performing adsorption operation. The upward-downward movement mechanism includes, for example, an actuator such as an air cylinder or a motor. For example, the holding mechanism 12 adsorbs the substrate 100 in a state in which the holding mechanism 12 moves up to an adsorption position. The holding mechanism 12 moves down to a standby position in a state in which adsorption is canceled.

The holding mechanism 12 holds the substrate 100 by sucking a surface (lower surface) of the substrate 100 on a side opposite a surface (upper surface) irradiated with the laser beam 15, in other words, a surface of the substrate 100 on a side facing the levitation unit 10. In FIG. 1, the holding mechanism 12 holds an end part of the substrate 100 in the +y direction.

The moving mechanism 13 included in the conveyance unit 11 is coupled to the holding mechanism 12. The moving mechanism 13 is configured to be able to move the holding mechanism 12 in the conveyance direction. The conveyance unit 11 (the holding mechanism 12 and the moving mechanism 13) is provided on an end part side of the levitation unit 10 in the +y direction, and the substrate 100 is conveyed as the moving mechanism 13 moves in the conveyance direction while the substrate 100 is held by the holding mechanism 12.

As illustrated in FIG. 1, for example, the moving mechanism 13 is configured to slide in the conveyance direction at the end part of the levitation unit 10 in the +y direction. The substrate 100 is conveyed in the conveyance direction as the moving mechanism 13 slides the end part of the levitation unit 10 in the conveyance direction. The conveyance direction is a direction tilted from the x direction. For example, θ is larger than 0° where θ is the angle between the x direction and the conveyance direction.

Accordingly, the levitation unit 10 has a trapezoid shape having four sides when viewed from top. Specifically, the levitation unit 10 has two sides parallel to the y direction of the levitation unit 10, one side parallel to the x direction, and one side (also referred to as a tilted side 10e) tilted from the x direction. The angle θ may be 0°. In other words, the conveyance direction may be parallel to the X direction. In this case, the levitation unit 10 has a rectangular planar shape.

The conveyance speed of the substrate 100 can be controlled by controlling the moving speed of the moving mechanism 13. The moving mechanism 13 includes, for example, a non-illustrated actuator such as a motor, a linear guide mechanism, and an air bearing. The moving mechanism 13 includes a guide mechanism such as a cable bearer (registered trademark).

The substrate 100 is irradiated with the laser beam 15. The irradiation region 15a of the laser beam 15 on the substrate 100 is linear with the y direction as the longitudinal direction. Accordingly, the irradiation region 15a has a longitudinal direction (line direction) along the y direction and has a transverse direction along the x direction.

For example, the laser irradiation unit 14 includes an excimer laser beam source or the like that generates the laser beam. The laser irradiation unit 14 additionally includes an optical system that guides the laser beam to the substrate 100. The laser irradiation unit 14 includes a lens that focuses the laser beam 15 onto the substrate 100. For example, the laser irradiation unit 14 includes a cylindrical lens for forming the linear irradiation region 15a. The substrate 100 is irradiated with the laser beam 15 (line beam) that is linear, and specifically, has a focal point extending in the y direction. The focal point of the laser beam 15 is formed on the substrate 100. Thus, high accuracy is requested for the amount of levitation in the precise levitation region 31 to reduce in-plane variance.

The substrate 100 is, for example, a glass substrate on which an amorphous film (amorphous silicon film 101a) is formed. The amorphous film can be crystallized by irradiating the amorphous film with the laser beam 15 and annealing. For example, the amorphous silicon film 101a can be converted into a polycrystalline silicon film (poly-silicon film 101b).

In the laser irradiation apparatus 1, while the substrate 100 is levitated by using the levitation unit 10, the lower surface of the substrate 100 is held by using the conveyance unit 11 and the substrate 100 is conveyed in the conveyance direction. The conveyance unit 11 included in the laser irradiation apparatus 1 conveys the substrate 100 while holding a position where the conveyance unit 11 does not overlap the irradiation region 15a in a plan view (when viewed in the z direction) when the substrate 100 is conveyed. In other words, as illustrated in FIG. 1, a position (corresponding to the position of the holding mechanism 12) where the conveyance unit 11 holds the substrate 100 does not overlap on the irradiation region 15a when the substrate 100 is conveyed in the conveyance direction.

For example, the substrate 100 has a rectangular (quadrilateral) planar shape having four sides, and the conveyance unit 11 (holding mechanism 12) holds only one of the four sides of the substrate 100. The conveyance unit 11 (holding mechanism 12) holds a position not irradiated with the laser beam in a duration in which the substrate 100 is conveyed.

With such a configuration, the position (corresponding to the position of the holding mechanism 12) where the conveyance unit 11 holds the substrate 100 and the irradiation region 15a can be separated from each other. The irradiation region 15a is substantially half of the −y side of the substrate 100, and the conveyance unit 11 holds its end part on the +y side. The distance between a place where deflection is large in the vicinity of the holding mechanism 12 and the irradiation region 15a can be increased. Thus, influence on the substrate 100 from deflection attributable to the holding mechanism 12 at laser irradiation can be reduced.

The length of the irradiation region 15a in the y direction is a length substantially half of the substrate 100. Accordingly, the amorphous silicon film 101a is crystallized in a substantially half region of the substrate 100 when the substrate 100 passes through the irradiation region 15a once. After the substrate 100 is rotated by 180° about the z axis by a non-illustrated rotary mechanism, the conveyance unit 11 conveys the substrate 100 in the −x direction. Alternatively, the substrate 100 rotated may be conveyed in the −x direction and then may be conveyed in the +x direction again by the conveyance unit 11. The substrate 100 is irradiated with the laser beam during conveyance in the −x direction or conveyance in the +x direction again after rotation by 180°. Accordingly, the substrate 100 passes through the irradiation region 15a, and the amorphous silicon film 101a is crystallized in the remaining half region of the substrate 100. In this manner, the amorphous silicon film 101a is converted into the poly-silicon film 101b on substantially the entire substrate 100 as the substrate 100 is reciprocated.

The conveyance direction is tilted from the x direction orthogonal to the linear irradiation region 15a. In other words, the substrate 100 is conveyed in the conveyance direction tilted from an end side of the substrate 100 in a quadrilateral shape. Substrate conveyance suitable for a laser irradiation process can be achieved when the conveyance direction is a direction tilted from the x direction when viewed from top. Thus, a silicon film crystallization process can be appropriately performed and display quality can be improved. With this configuration, for example, moire generation can be prevented.

For example, the substrate 100 is a glass substrate for an organic light-emitting diode display apparatus. In a case where the organic light-emitting diode display apparatus has a quadrilateral display region, end sides of the display region are disposed in parallel to end sides of the substrate 100. Accordingly, organic light-emitting diode display apparatus includes a quadrilateral display region having short sides in the x direction and the y direction. In a case where the conveyance direction is parallel to the x direction, the substrate 100 is irradiated with the laser beam in a state in which a pixel array direction and the irradiation region 15a are parallel to each other.

As described in the present embodiment, a laser irradiation process can be appropriately performed when the conveyance direction is a direction tilted from the x direction. The moving mechanism 13 moves the holding mechanism 12 in the conveyance direction tilted from the x direction orthogonal to the longitudinal direction of the linear irradiation region 15a when viewed from top to change a laser irradiation position on the substrate 100. Thus, a silicon film crystallization process can be appropriately performed. For example, moire generation can be prevented and display quality can be improved.

### Orbiting Conveyance

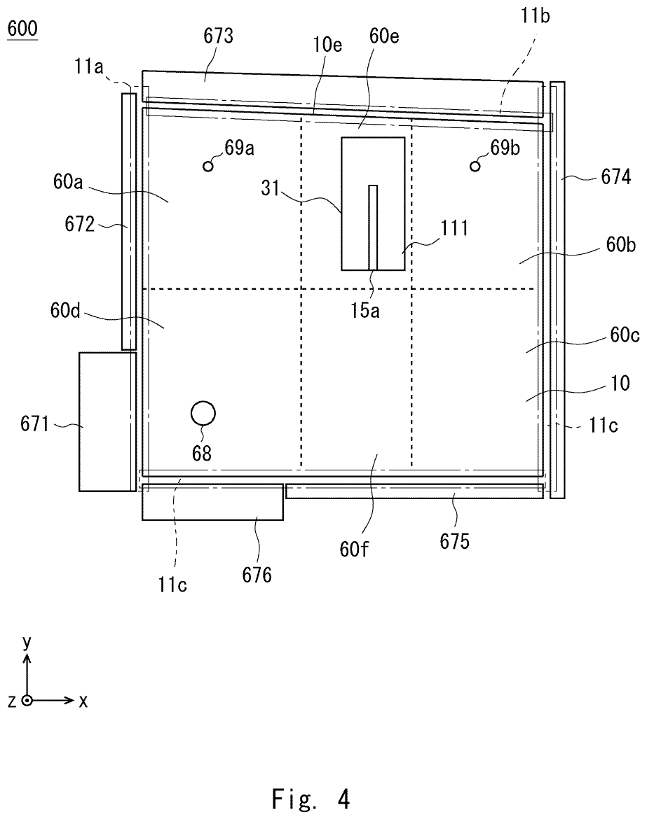

The configuration of the conveyance apparatus 600 will be described next with reference to FIG. 4. FIG. 4 is a top view illustrating the configuration of the conveyance apparatus 600. Note that description of the same contents as contents of the above description with reference to FIGS. 1 to 3 is omitted as appropriate. Although the conveyance apparatus 600 includes a displacement meter 129, a cooling unit 1201b, an exhaust mechanism 170, and the like to be described later, these components are omitted in FIG. 4. Note that the displacement meter 129, the cooling unit 1201b, the exhaust mechanism 170, and the like may be omitted as appropriate.

The conveyance apparatus 600 includes the levitation unit 10 and end part levitation units 671 to 676. The levitation unit 10 levitates a substrate (not illustrated in FIG. 4) that is a processing target body. The levitation unit 10 has a trapezoid shape when viewed from top. The levitation unit 10 has two sides parallel to the y direction, one side parallel to the x direction, and one side (also referred to as the tilted side 10e) tilted from the x direction. The angle between the tilted side 10e and the x direction is preferably larger than 0°. The end part levitation units 671 to 676 levitate substrate end parts protruding from the levitation unit 10.

Hereinafter, the levitation unit 10 is divided into six regions 60a to 60f when viewed from top for purpose of description. Specifically, the levitation unit 10 includes the first region 60a to the fourth region 60d, a process region 60e, and a passing region 60f. The first region 60a is a trapezoid region including a corner (upper-left corner in FIG. 4) on the −x side and the +y side. The second region 60b is a trapezoid region including a corner (upper-right corner in FIG. 4) on the +x side and the +y side. The third region 60c is a quadrilateral region including a corner (lower-right corner in FIG. 4) on the +x side and the −y side. The fourth region 60d is a quadrilateral region including a corner (lower-left corner in FIG. 4) on the −x side and the −y side.

The process region 60e is a trapezoid region disposed between the first region 60a and the second region 60b. The process region 60e is a region including the irradiation region 15a to be irradiated with the laser beam. The passing region 60f is a quadrilateral region disposed between the third region 60c and the fourth region 60d.

The half region (upper half region in FIG. 4) of the levitation unit 10 on the +y side is the first region 60a, the process region 60e, and the second region 60b in order from the −x side (left side in FIG. 4). The half region (lower half region in FIG. 4) of the levitation unit on the −y side is the third region 60c, the passing region 60f, and the fourth region 60d in order from the +x side.

The fourth region 60d is a loading region where the substrate 100 is loaded, and an unloading region where the substrate 100 is unloaded. For example, a transfer machine (not illustrated) such as a transfer robot is provided on the −x side of the fourth region 60d. The transfer machine loads the substrate 100 into the fourth region 60d. Similarly, the transfer machine unloads the substrate in the fourth region 60d. A pusher pin may be used for loading and unloading of the substrate 100.

The levitation unit 10 includes the rotary mechanism 68 and alignment mechanisms 69a and 69b. The rotary mechanism 68 rotates the substrate. The alignment mechanisms 69a and 69b align the substrate. The alignment mechanisms 69a and 69b are provided in the first region 60a and the second region 60b, respectively. The rotary mechanism 68 is provided in the fourth region 60d. Operation of the rotary mechanism 68, the alignment mechanisms 69a and 69b, and the like will be described later.

The end part levitation units 671 to 676 are disposed outside the levitation unit 10. The end part levitation units 671 to 676 are disposed along the outer periphery of the levitation unit 10 in a trapezoid shape. The end part levitation units 671 to 676 are provided along end sides of the levitation unit 10. The end part levitation units 671 to 676 are disposed to surround the outer periphery of the levitation unit 10 when viewed from top.

The end part levitation units 671 and 672 are disposed on the −x side of the levitation unit 10. The end part levitation unit 673 is disposed on the +y side of the levitation unit 10. The end part levitation unit 674 is disposed on the +x side of the levitation unit 10. The end part levitation units 675 and 676 are disposed on the −y side of the levitation unit 10.

The end part levitation units 671 and 672 are disposed along an end side of the levitation unit 10 on the −x side. Accordingly, the end part levitation units 671 and 672 are each provided in the y direction. The width of the end part levitation unit 671 in the x direction is wider than that of the end part levitation unit 672. The end part levitation unit 671 is disposed on the-y side of the end part levitation unit 672.

The end part levitation unit 673 is disposed along an end side of the levitation unit 10 on the +y side. Accordingly, the end part levitation unit 673 is provided along the tilted side 10e of the levitation unit 10. The end part levitation unit 674 is disposed along an end side of the levitation unit 10 on the +x side. Accordingly, the end part levitation unit 674 is provided in the y direction.

The end part levitation units 675 and 676 are disposed along an end side of the levitation unit 10 on the −y side. Accordingly, the end part levitation units 675 and 676 are each provided in the x direction. The width of the end part levitation unit 676 in the y direction is wider than that of the end part levitation unit 675. The end part levitation unit 676 is disposed on the −x side of the end part levitation unit 675.

A conveyance unit 11a is provided between the levitation unit 10 and the end part levitation unit 671. The conveyance unit 11a is also disposed between the levitation unit 10 and the end part levitation unit 672. The conveyance unit 11a is formed in the y direction. The conveyance unit 11a conveys the substrate in the +y direction. Specifically, the conveyance unit 11a conveys the substrate 100 from the fourth region 60d toward the first region 60a.

A conveyance unit 11b is provided between the levitation unit 10 and the end part levitation unit 673. The conveyance unit 11b is formed along the tilted side 10e. The conveyance unit 11b conveys the substrate in a direction parallel to the tilted side 10e. Specifically, the conveyance unit 11b conveys the substrate 100 from the first region 60a toward the second region 60b.

A conveyance unit 11c is provided between the levitation unit 10 and the end part levitation unit 674. The conveyance unit 11c is formed in the y direction. The conveyance unit 11c conveys the substrate 100 in the −y direction. Specifically, the conveyance unit 11c conveys the substrate 100 from the second region 60b toward the third region 60c.

A conveyance unit 11d is provided between the levitation unit 10 and the end part levitation unit 675. The conveyance unit 11d is also disposed between the levitation unit 10 and the end part levitation unit 676. The conveyance unit 11d is formed in the x direction. The conveyance unit 11a conveys the substrate in the −x direction. Specifically, the conveyance unit 11d conveys the substrate from the third region 60c toward the fourth region 60d.

Note that the conveyance units 11a to 11d each include the holding mechanism 12 and the moving mechanism 13 illustrated in FIG. 1. Operation of the holding mechanism 12 and the moving mechanism 13 will be described later.

The irradiation region 15a of the laser beam has a longitudinal direction in the y direction. In other words, the linear irradiation region 15a having a longitudinal direction in the y direction is formed. The substrate 100 is irradiated with the laser beam while the substrate 100 is conveyed in the direction parallel to the tilted side 10e. A laser irradiation process is executed while the substrate 100 is moved from the first region 60a to the second region 60b. In the present embodiment as well, an amorphous silicon film is converted into a poly-silicon film by irradiating a substrate with a laser beam from a laser beam source.

Note that, in the levitation unit 10, the precise levitation units 111 are disposed in and around the irradiation region 15a. The precise levitation units 111 have a higher accuracy of levitation amount than the semi-precise levitation units and the rough levitation units in the other region. Thus, the substrate 100 being levitated with the amount of levitation at higher accuracy is irradiated with the laser beam in the process region 60e including the irradiation region 15a than in the other regions 60a to 60d and 60f. Accordingly, the substrate 100 can be stably irradiated with the laser beam. The other regions than the irradiation region 15a, for example, the passing region 60f, the third region 60c, and the fourth region 60d are produced without using the precise levitation units 111 that are expensive. Thus, apparatus cost can be reduced.

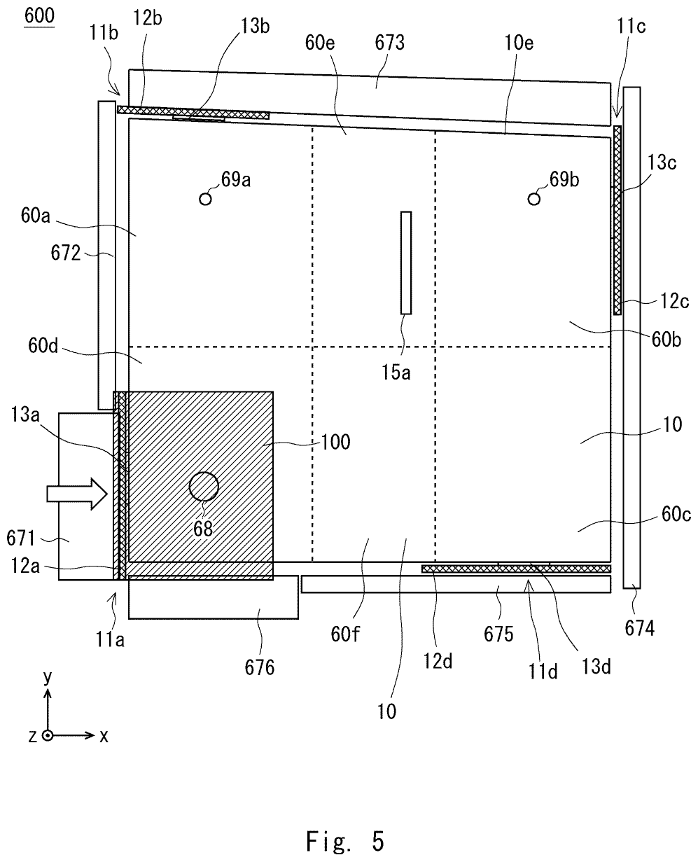

The procedure of a conveyance method using the levitation unit 10 will be described next with reference to FIGS. 5 to 12. In this example, the fourth region 60d is the loading position and unloading position of the substrate 100. The substrate 100 loaded into the fourth region 60d is conveyed through the first region 60a, the process region 60e, the second region 60b, the third region 60c, the passing region 60f, and the fourth region 60d in the stated order. Accordingly, the substrate 100 orbits along the end sides of the levitation unit 10. The substrate 100 orbits twice to irradiate the entire substrate 100 with the laser beam. In other words, the substrate 100 is conveyed to circulate twice over the levitation unit 10. In this manner, substantially the entire surface of the substrate 100 is irradiated with the laser beam.

The following description is performed in detail along the procedure of the conveyance method. As illustrated in FIG. 5, the substrate 100 is loaded into the fourth region 60d. The substrate 100 loaded into the fourth region 60d is levitated by the levitation unit 10 and the end part levitation units 671, 672, and 676. Specifically, the end part of the substrate 100 on the −x side is levitated by the end part levitation units 671 and 672, and a central part thereof is levitated by the levitation unit 10. The end part of the substrate 100 on the −y side is levitated by the end part levitation unit 676. A holding mechanism 12a of the conveyance unit 11a holds the substrate 100.

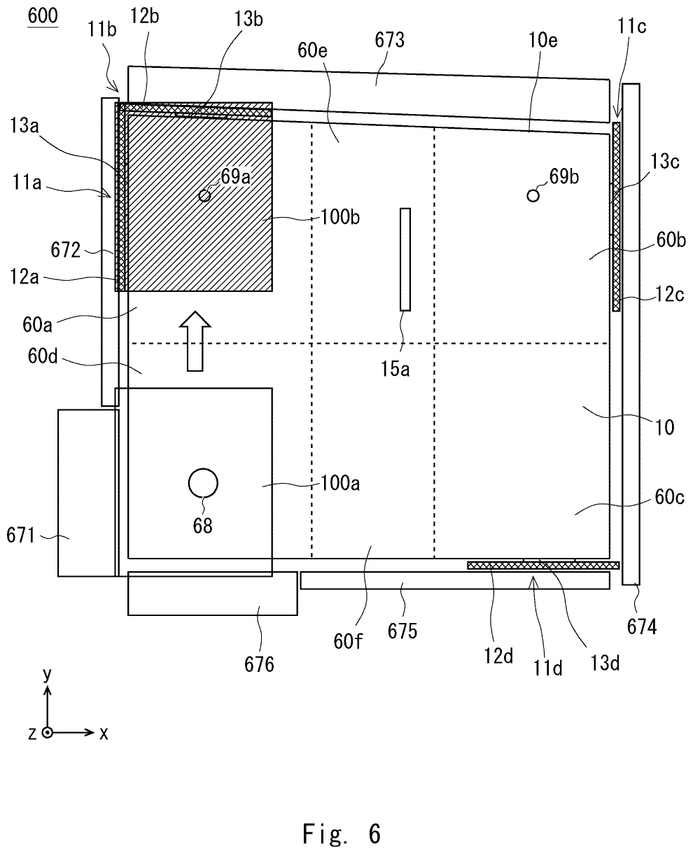

Subsequently, as illustrated in FIG. 6, a substrate 100a in the fourth region 60d is conveyed to the first region 60a. In FIG. 6, the substrate having moved to the first region 60a is illustrated as a substrate 100b. The holding mechanism 12a of the conveyance unit 11a holds the substrate 100a. Then, the substrate 100a is moved from the fourth region 60d to the first region 60a (white arrow in FIG. 6) as a moving mechanism 13a moves the holding mechanism 12a in the +y direction.

The holding mechanism 12a passes between the levitation unit 10 and the end part levitation unit 671 in an xy plan view and moves in the +y direction. In addition, the holding mechanism 12a passes between the levitation unit 10 and the end part levitation unit 672 in an xy plan view and moves in the +y direction. Accordingly, the substrate 100b is levitated by the levitation unit 10 and the end part levitation units 672 and 673. Specifically, the end part of the substrate 100b on the −x side is levitated by the end part levitation unit 672, and a central part thereof is levitated by the levitation unit 10. The end part of the substrate 100b on the +y side is levitated by the end part levitation unit 673.

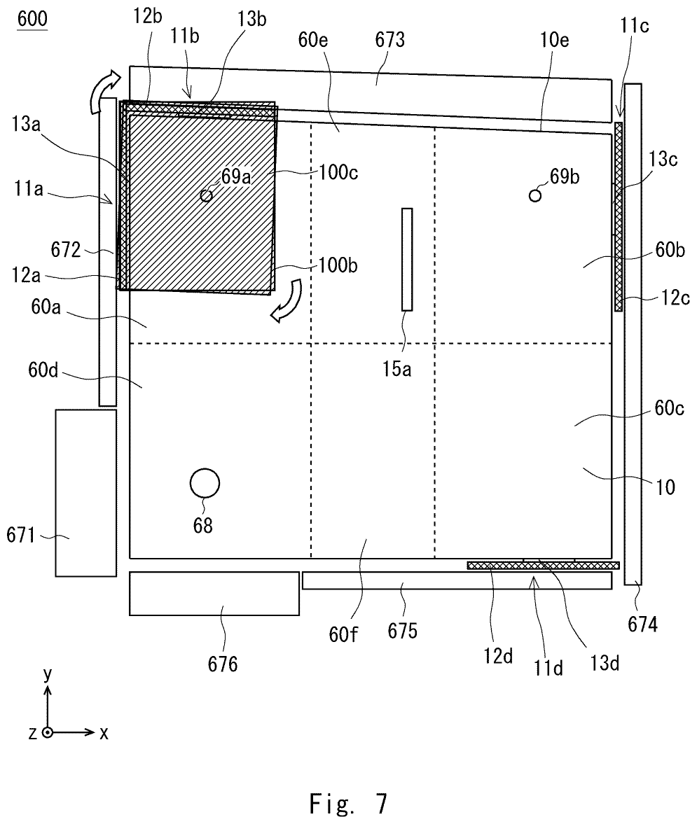

Subsequently, as illustrated in FIG. 7, the alignment mechanism 69a aligns the position and angle of the substrate 100b conveyed to the first region 60a. The position and rotation angle of the substrate 100 are slightly shifted due to, for example, loading operation, conveyance operation, and rotation operation of the substrate in some cases. The alignment mechanism 69a corrects shift in the position and the rotation angle. Accordingly, the irradiation position of the laser beam on the substrate 100 can be accurately controlled.

For example, the alignment mechanism 69a is movable in the y direction and rotatable about the z axis. In addition, the alignment mechanism 69a is movable in the z direction. For example, the alignment mechanism 69a includes an actuator such as a motor. The amount of positional shift and the amount of angle shift are determined based on an image of the substrate 100b captured by a camera or the like. The alignment mechanism 69a performs alignment based on the shift amounts.

The alignment mechanism 69a is disposed directly below the central part of the substrate 100b. The alignment mechanism 69a holds the substrate 100b. Similarly to the holding mechanism 12, the alignment mechanism 69a may hold the substrate 100b by adsorption.

The holding mechanism 12a releases holding of the substrate 100b. Accordingly, the substrate 100b is handed over from the holding mechanism 12a to the alignment mechanism 69a.

Then, the alignment mechanism 69a rotates the substrate 100b about the z axis (white arrow in FIG. 7). The alignment mechanism 69a rotates the substrate 100b so that an end side of the substrate 100b becomes parallel to the tilted side 10e of the levitation unit 10. The substrate after the rotation is illustrated as a substrate 100c. For example, the alignment mechanism 69a rotates the substrate 100 by a predetermined angle about the z axis. An end side of the substrate 100c is parallel to the tilted side 10e of the levitation unit 10. After the alignment ends, a holding mechanism 12b of the conveyance unit 11b holds the substrate 100b, and the alignment mechanism 69a releases the holding. Accordingly, the substrate 100c is handed over from the alignment mechanism 69a to the holding mechanism 12b of the conveyance unit 11b.

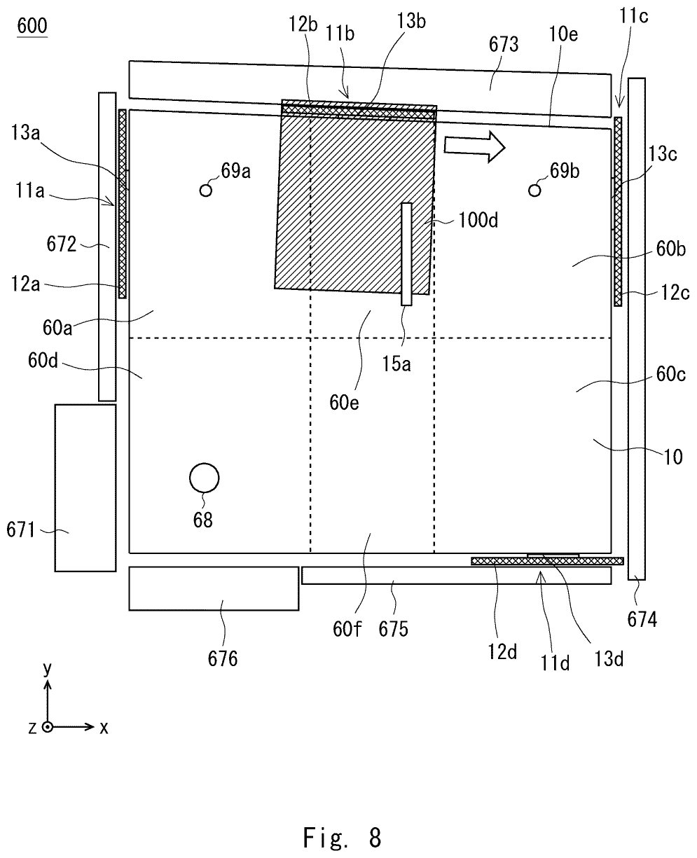

Subsequently, as illustrated in FIG. 8, the conveyance unit 11b moves a substrate 100d. Accordingly, the substrate 100d passes through the process region 60e. The holding mechanism 12b passes between the levitation unit 10 and the end part levitation unit 673 in an xy plan view and moves in the direction parallel to the tilted side 10e. Accordingly, a substantially half region of the substrate 100d passes through the irradiation region 15a. The substrate 100d moving in a tilt direction tilted from the x direction orthogonal to the irradiation region 15a is irradiated with the laser beam.

The holding mechanism 12b passes between the levitation unit 10 and the end part levitation unit 673 in an xy plan view and moves in the direction parallel to the tilted side 10e. Accordingly, the substrate 100d is levitated by the levitation unit 10 and the end part levitation unit 673. Specifically, an end part of the substrate 100d on the +y side is levitated by the end part levitation unit 673, and a central part thereof is levitated by the levitation unit 10. A laser irradiation process is performed while the substrate 100d is moved from the first region 60a to the second region 60b.

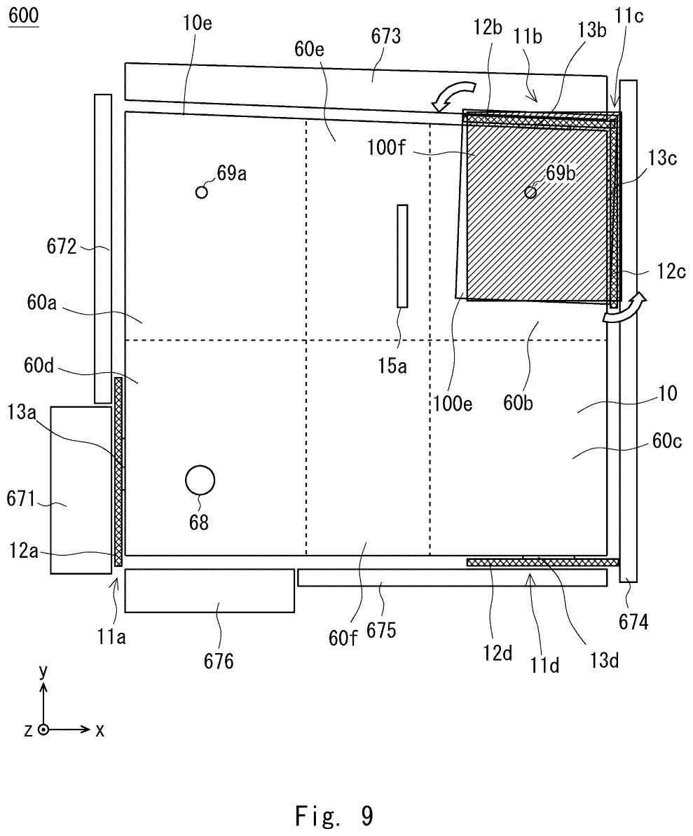

Subsequently, as illustrated in FIG. 9, the alignment mechanism 69b aligns a substrate 100e after the substrate 100e is moved to the second region 60b. Specifically, the alignment mechanism 69b rotates the substrate 100e (white arrow in FIG. 9). In FIG. 9, the substrate after rotation is illustrated as a substrate 100f.

The alignment mechanism 69b is disposed directly below a central part of the substrate 100e. The alignment mechanism 69b holds the substrate 100e. Similarly to the holding mechanism 12, the alignment mechanism 69b may hold the substrate 100e by adsorption. Further, the holding mechanism 12b releases holding of the substrate 100e. The substrate 100e is handed over from the holding mechanism 12b of the conveyance unit 11b to the alignment mechanism 69b.

The alignment mechanism 69b rotates the substrate 100e about the z axis (white arrow in FIG. 9). The alignment mechanism 69a rotates the substrate 100e so that an end side of the substrate 100e becomes parallel to the tilted side 10e of the levitation unit 10. The end side of the substrate 100f after the rotation is parallel to the x direction or the y direction. After the alignment ends, a holding mechanism 12c of the conveyance unit 11c holds the substrate 100f, and the alignment mechanism 69b releases the holding. Accordingly, the substrate 100f is handed over from the alignment mechanism 69b to the holding mechanism 12c of the conveyance unit 11c.

The substrate 100e is levitated by the levitation unit 10 and the end part levitation units 673 and 674. Specifically, an end part of the substrate 100e on the +y side is levitated by the end part levitation unit 673. An end part of the substrate 100e on the +x side is levitated by the end part levitation unit 674, and a central part thereof is levitated by the levitation unit 10.

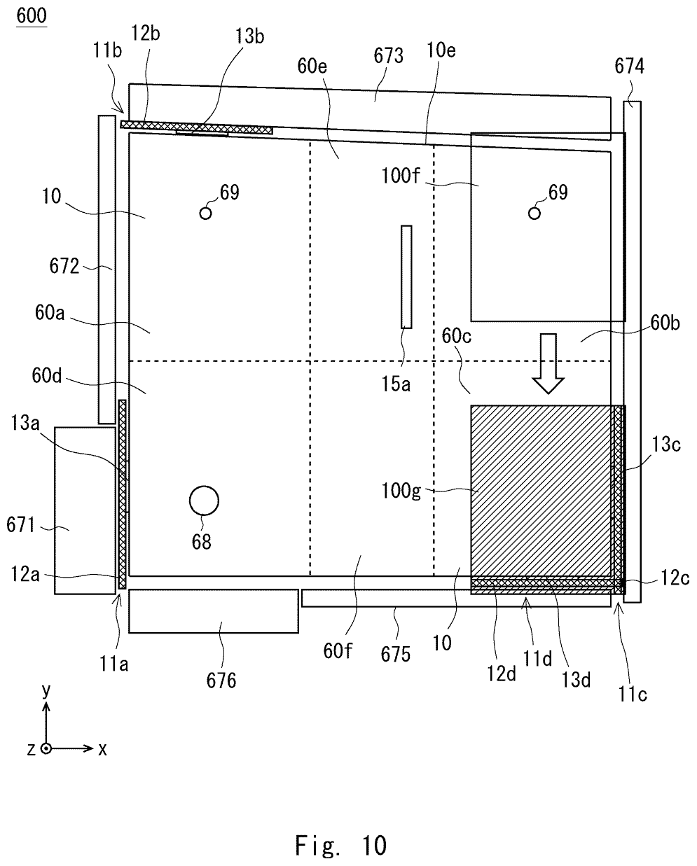

Subsequently, as illustrated in FIG. 10, the substrate 100f in the second region 60b is conveyed to the third region 60c. The substrate having moved to the third region 60c is illustrated as a substrate 100g. In FIG. 10, the holding mechanism 12c of the conveyance unit 11c holds the substrate 100f. Then, the substrate 100f is moved from the second region 60b to the third region 60c (white arrow in FIG. 10) as a moving mechanism 13c moves the holding mechanism 12c in the −y direction.

The holding mechanism 12c passes between the levitation unit 10 and the end part levitation unit 674 in an xy plan view and moves in the −y direction. Accordingly, the substrate 100e is levitated by the levitation unit 10 and the end part levitation units 674 and 675. The end part of the substrate 100e on the +x side is levitated by the end part levitation unit 674, and the central part thereof is levitated by the levitation unit 10. An end part of the substrate 100e on the −y side is levitated by the end part levitation unit 675.

Then, a holding mechanism 12d of the conveyance unit 11d holds the substrate 100g, and the holding mechanism 12c releases the holding. Accordingly, the substrate 100g is handed over from the holding mechanism 12c of the conveyance unit 11c to the holding mechanism 12d of the conveyance unit 11d.

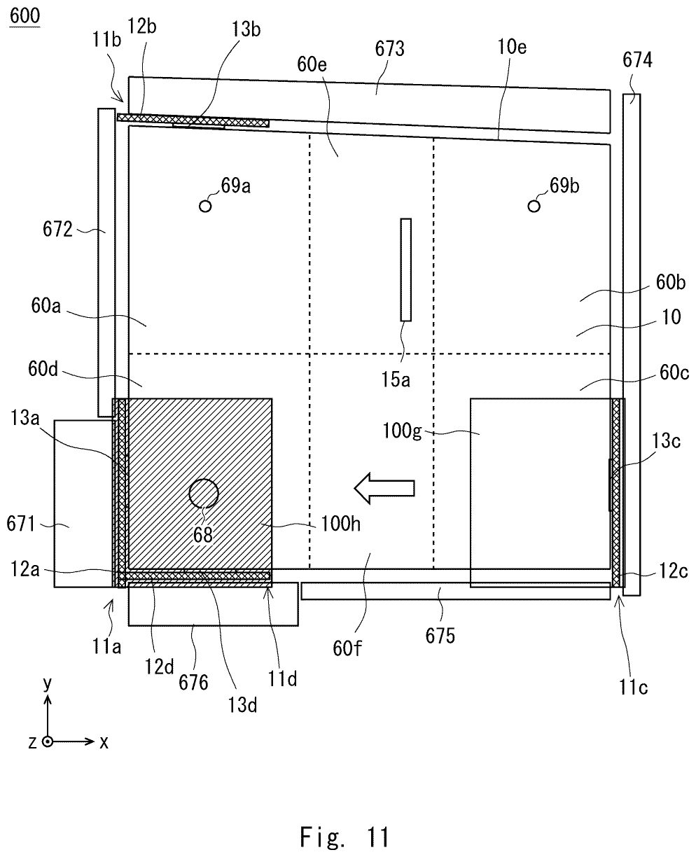

Subsequently, as illustrated in FIG. 11, the substrate 100g in the third region 60c is conveyed to the fourth region 60d. The substrate having moved to the fourth region 60d is illustrated as a substrate 100h. In FIG. 11, the holding mechanism 12d of the conveyance unit 11d holds the substrate 100g. Then, the substrate 100f is moved from the third region 60c to the fourth region 60d (white arrow in FIG. 11) as a moving mechanism 13d moves the holding mechanism 12d in the −x direction.

The holding mechanism 12d passes between the levitation unit 10 and the end part levitation unit 675 in an xy plan view and moves in the −x direction. The holding mechanism 12d passes between the levitation unit 10 and the end part levitation unit 676 in an xy plan view and moves in the −x direction. Accordingly, the substrate 100h is levitated by the levitation unit 10 and the end part levitation unit 676. An end part of the substrate 100h on the −y side is levitated by the end part levitation unit 676, and a central part thereof is levitated by the levitation unit 10. An end part of the substrate 100h on the −x side is levitated by the end part levitation unit 671.

In this manner, the substrate 100 in the fourth region 60d moves through the first region 60a, the process region 60e, the second region 60b, the third region 60c, the passing region 60f, and the fourth region 60d in the stated order. In other words, the substrate 100 orbits along the end sides of the levitation unit 10.

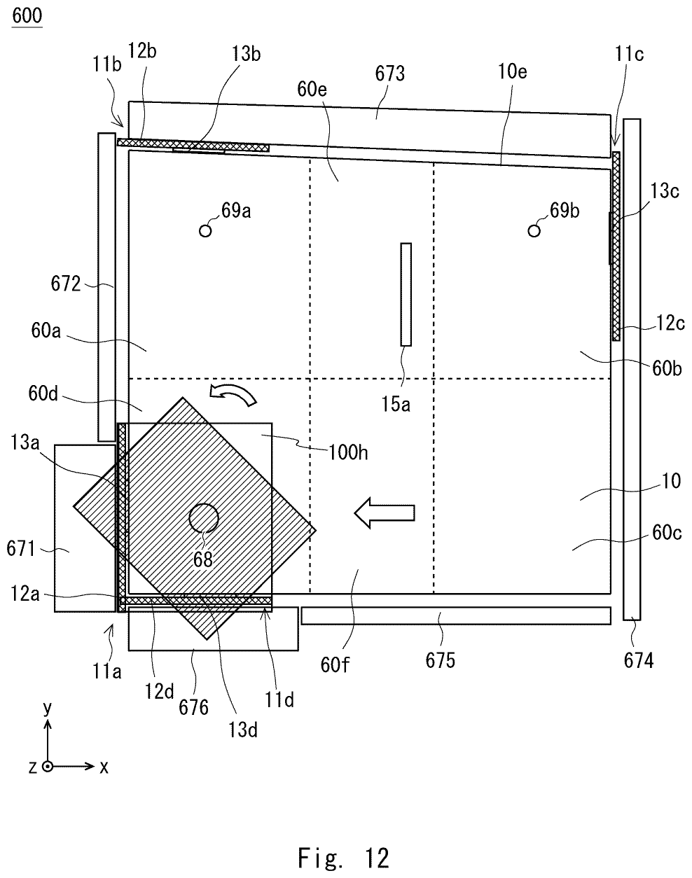

Subsequently, as illustrated in FIG. 12, the rotary mechanism 68 rotates the substrate 100h by 180° about the z axis. Accordingly, the substrate 100h is handed over from the holding mechanism 12d to the rotary mechanism 68. After the rotary mechanism 68 rotates the substrate 100h, the substrate 100h is handed over from the rotary mechanism 68 to the holding mechanism 12d.

In the same manner as described above, the conveyance units 11a to 11d moves the substrate 100h again through the first region 60a, the process region 60e, the second region 60b, the third region 60c, the passing region 60f, and the fourth region 60d in the stated order. In other words, the substrate 100 orbits along the end sides of the levitation unit 10 as illustrated in FIGS. 5 to 12.

The rotary mechanism 68 rotates the substrate 100h by 180°. As the substrate 100e passes through the process region 60e for the second time, the remaining half region not irradiated with the laser beam through the first passing is irradiated with the laser beam. In this manner, the substrate 100 circulates twice along the end sides of the levitation unit 10. Since the substrate 100 is rotated by 180° between the first laser irradiation and the second laser irradiation, substantially the entire surface of the substrate 100 is irradiated with the laser beam. Note that a position where the substrate 100 is rotated is not limited to the first region 60a. For example, the rotation may be performed in the second region 60b, the third region 60c, or the fourth region 60d.

In the present embodiment as well, a moving mechanism 13b conveys the holding mechanism 12b in a direction tilted from the x direction orthogonal to the irradiation region 15a. Thus, a silicon film crystallization process can be appropriately performed. For example, moire generation can be prevented and display quality can be improved. The conveyance direction of the substrate 100 may be the X direction. The conveyance direction of the substrate 100 only needs to be a direction tilted from the Y direction when viewed from top. Specifically, the conveyance direction of the substrate may be parallel to the X direction or may be a direction tilted from the X direction.

### Displacement Meter in Irradiation Region

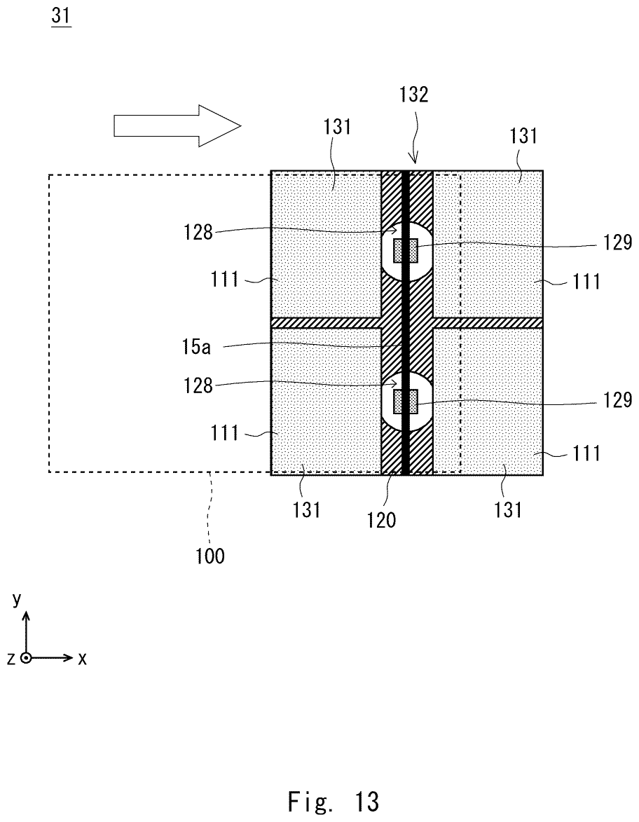

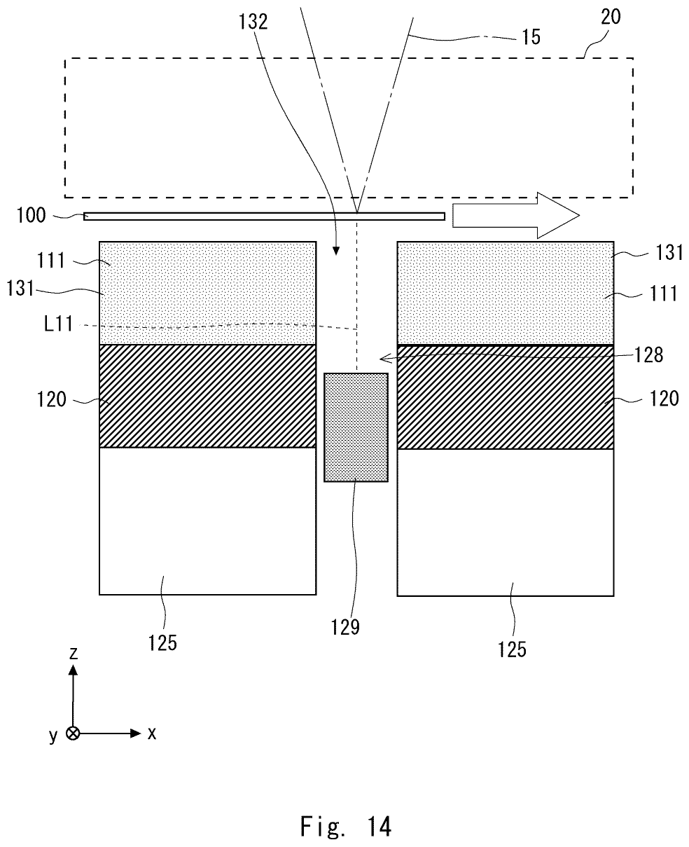

Components directly below the irradiation region 15a will be described next with reference to FIGS. 13 and 14. FIG. 13 is a plan view schematically illustrating the irradiation region 15a and its surrounding components in the precise levitation region 31. FIG. 14 is a side view schematically illustrating the irradiation region 15a and its surrounding components.

The displacement meter 129 is provided directly below the irradiation region 15a. The displacement meter 129 is disposed below the substrate 100. The displacement meter 129 is a laser displacement meter and measures the position of the substrate 100 in the Z direction. Thus, the displacement meter 129 can detect the levitation height of the substrate 100 in a non-contacting manner. For example, the displacement meter 129 includes a laser beam source configured to generate detection light L11 toward the substrate 100 and a light detector configured to detect reflected light from the substrate 100. The detection light L11 travels upward and is incident on the substrate 100 from below.

As illustrated in FIG. 14, the plurality of precise levitation units 111 are provided on the base 120. As illustrated in FIG. 13, the precise levitation units 111 each have a quadrilateral shape. The precise levitation units 111 are arranged in the X and Y directions.

The irradiation region 15a is a linear region having a longitudinal direction in the Y direction. A gap 132 is provided between two precise levitation units 111 arranged in the X direction. This gap 132 is a groove provided in the Y direction. The irradiation region 15a is positioned in the gap 132. Accordingly, the laser beam is incident on the substrate 100 directly above the gap 132.

A space 128 is provided at the base 120 and the reference plate 125 directly below the gap 132. The space 128 is a space for disposing the displacement meter 129. For example, a recess or a through-hole formed at the base 120 serves as the space 128. In FIG. 14, the space 128 penetrates through the reference plate 125. Accordingly, the upper side of the levitation unit cells 131 and the lower side of the reference plate 125 are connected to each other through the gap 132 and the space 128. Note that in a case where the space 128 penetrates to the lower side of the reference plate 125, a signal line of the displacement meter 129 may be taken out from the lower side of the space 128. The displacement meter 129 is disposed directly below the gap 132.

The displacement meter 129 is an optical displacement meter and emits the detection light L11 upward. The detection light L11 passes through the space 128 and the gap 132 and is incident on the substrate 100. Similarly, reflected light from the substrate 100 passes through the gap 132 and the space 128 and is incident on the displacement meter 129.

Note that the space 128 provided at the base 120 may be a space for the detection light L11 to pass through. Thus, the displacement meter 129 does not necessarily need to be disposed inside the base 120. The displacement meter 129 may be disposed lower than the base 120. In this case, the height of the displacement meter 129 may be the same as or lower than the height of the reference plate 125. Thus, part of the displacement meter 129 may be disposed inside the reference plate 125, or the displacement meter 129 may be disposed lower than the reference plate 125.

With this configuration, the levitation height of the substrate 100 in the irradiation region 15a can be measured. Thus, the substrate 100 can be conveyed at an appropriate levitation height. Specifically, gas ejection and gas suction can be controlled to achieve an optimum levitation height. The irradiation process of the laser beam can be appropriately controlled. Specifically, the levitation height of the substrate 100 at or near the irradiation position of the laser beam can be appropriately managed, and thus the levitation height of the substrate 100 at the irradiation position of the laser beam can be maintained constant.

Energy density of the laser beam on the substrate 100 can be maintained constant and stable laser irradiation is possible. Alternatively, irradiation intensity of the laser beam may be controlled in accordance with the levitation height. Process conditions can be controlled in accordance with measured levitation height. Thus, a more uniform polysilicon film can be formed.

A plurality of displacement meters 129 are provided in the line direction. For example, four displacement meters 129 are provided in FIG. 13. The four displacement meters 129 are disposed at predetermined intervals. With this configuration, levitation height distribution in the line direction can be detected. Thus, the levitation height in the line direction can be made uniform.

For example, four precise levitation units 111 are arranged in the Y direction in the precise levitation region 31. A displacement meter 129 is disposed near the center of each precise levitation unit 111 in the Y direction. In other words, precise levitation units 111 are disposed next to four displacement meters 129, respectively, in the X direction. Gas ejection and gas supply at each precise levitation unit 111 can be independently controlled. Gas ejection and gas supply of each precise levitation unit 111 are controlled based on the levitation height detected by the corresponding displacement meter 129. Thus, levitation height in the line direction can be made uniform. Accordingly, a more stable process is possible and a uniform polysilicon film can be formed.

The conveyance method according to the present embodiment conveys the substrate by using the above-described conveyance apparatus 600. The conveyance method includes a step of holding the substrate 100 by the holding mechanism 12 and a step of conveying the substrate 100 over the levitation unit 10 by moving the holding mechanism 12 by the moving mechanism 13. The levitation height of the substrate 100 being conveyed is measured by each displacement meter 129.

### Cooling Mechanism of Base 120

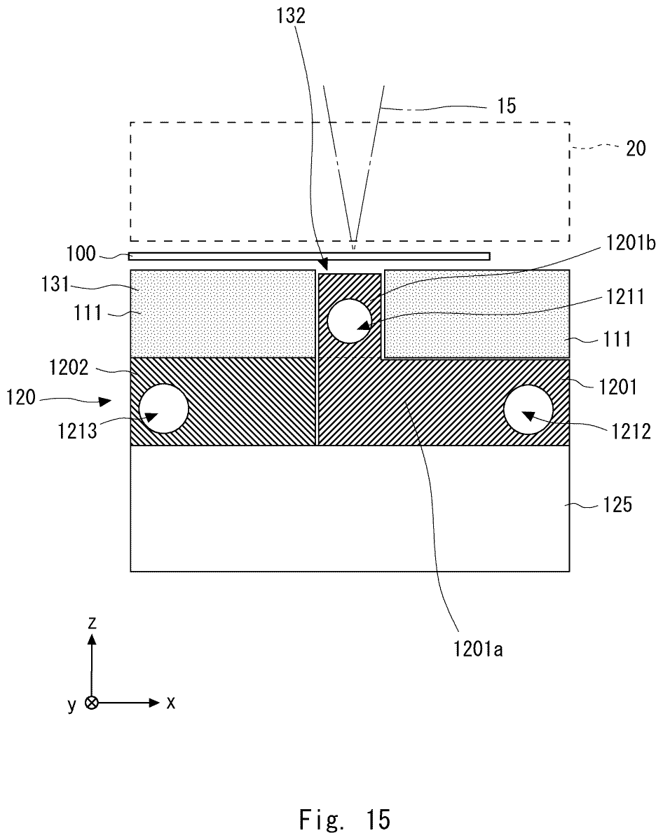

A cooling mechanism provided at the base 120 will be described next with reference to FIG. 15. FIG. 15 is a side cross-sectional view illustrating the gap 132 directly below the irradiation region 15a and its surrounding components. A cooling path through which cooling water flows is provided at the base 120. With this configuration, cooling water flows inside the base 120, and thus temperature increase due to laser irradiation can be reduced.

An example of the configuration of the base 120 will be described below. The base 120 is divided into two cooling blocks 1201 and 1202. The plurality of cooling blocks function as the base 120. The cooling blocks 1201 and 1202 are formed of a metallic material such as aluminum alloy.

The cooling block 1202 is disposed directly below precise levitation units 111 disposed on the −X side of the gap 132. Specifically, the cooling block 1202 is a flat block disposed between the precise levitation units 111 and the reference plate 125. The cooling block 1202 has a quadrilateral shape in an XZ plan view. A cooling path 1213 is formed in the cooling block 1202. In this example, the cooling path 1213 is provided in the Y direction but may meander in the cooling block 1202. Each end of the cooling path 1213 reaches a bottom surface or side surface of the cooling block 1202. Cooling water is supplied from one end of the cooling path 1213 and discharged from the other end. The cooling path 1213 functions as a cooling pipe in which cooling water flows.

The cooling block 1201 is disposed directly below precise levitation units 111 disposed on the +X side of the gap 132. The cooling block 1201 is formed in an L shape in an XZ plan view. Specifically, the cooling block 1201 includes a flat plate base part 1201a and the cooling unit 1201b protruding upward from the base part 1201a.

The cooling unit 1201b is disposed in the gap 132. Specifically, the cooling unit 1201b has an upper surface at height substantially same as the upper surfaces (levitation surface) of the precise levitation units 111. Accordingly, the height of the cooling block 1202 at the gap 132 is aligned with the height of the levitation surface of the precise levitation units 111. Thus, disorder in airflow of inert gas from the seal box 20 and levitation gas from the precise levitation units 111 can be prevented to achieve accurate levitation. The upper surface of the cooling unit 1201b is lower than the upper surfaces of the precise levitation units 111 in FIG. 15 but may have the same height.

In addition, a cooling path 1211 extending in the line direction is provided in the cooling unit 1201b. The cooling path 1211 is disposed in the gap 132. Each end of the cooling path 1211 is connected to a side surface or bottom surface of the cooling block 1201. A cooling path 1212 is provided in the base part 1201a. The cooling path 1212 may meander in the base part 1201a. Each end of the cooling path 1212 is connected to the side surface or bottom surface of the cooling block 1201. The cooling path 1211 and the cooling path 1212 may be connected to each other. For example, the cooling path 1211 may be provided to bend downward. Cooling water is supplied from one end of each of the cooling path 1211 and the cooling path 1212 and discharged from the other end. The cooling paths 1211 and 1212 each function as a cooling pipe in which cooling water flows. With this configuration, the cooling block 1201 can be cooled.

The cooling path 1211 is provided in the gap 132 directly below the irradiation region 15a of the laser beam 15. The cooling path 1211 is disposed at the height of the precise levitation units 111. With this configuration, temperature increase due to irradiation with the laser beam 15 can be effectively reduced. For example, when temperature increases around the precise levitation units 111 due to laser beam irradiation, the temperature of the precise levitation units 111 increases as well. As a result, the precise levitation units 111 locally thermally expand, and levitation accuracy potentially decreases. The base 120 includes the cooling path 1211 disposed in the gap 132. With this configuration, temperature increase of the precise levitation units 111 can be reduced, and thus degradation of levitation accuracy can be reduced. Accordingly, the laser irradiation process can be stably performed.

### Cooling Mechanism and Displacement Meter

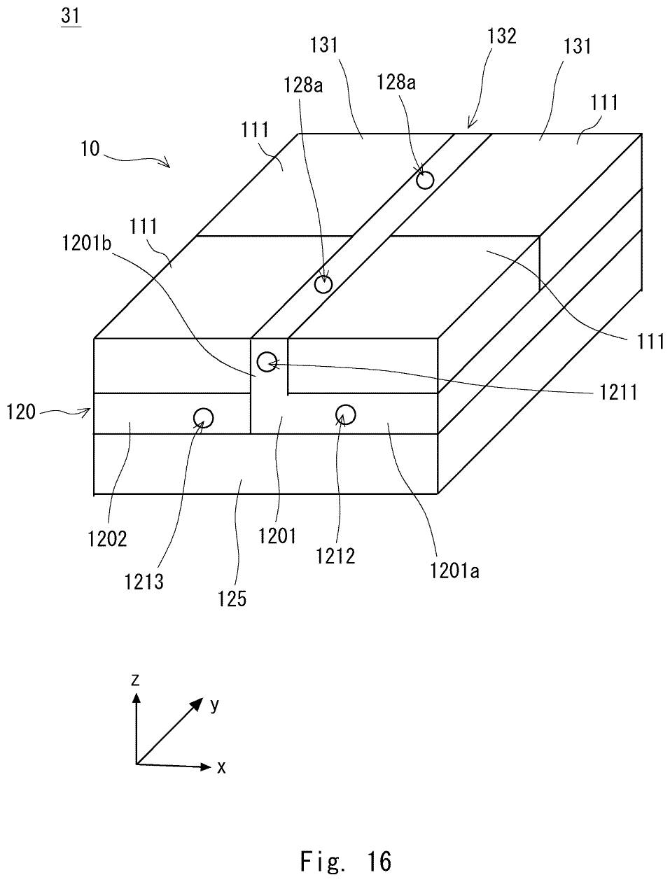

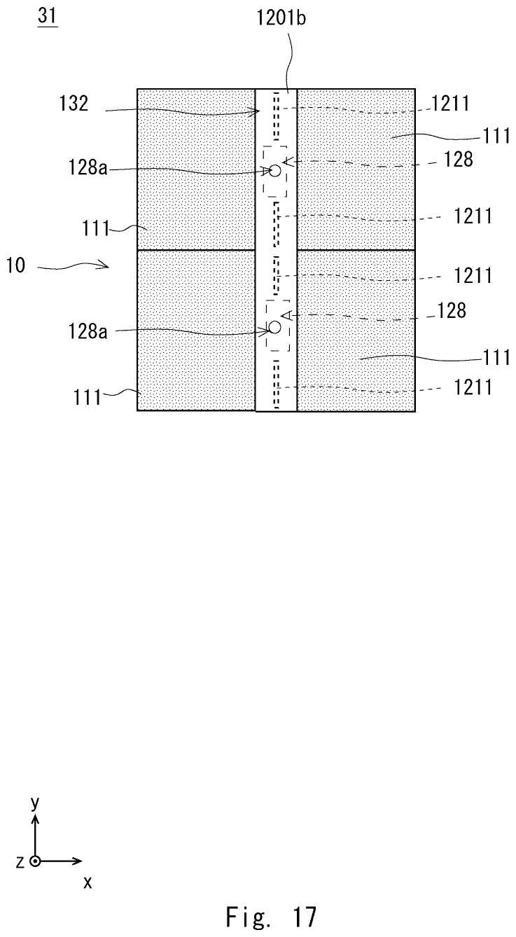

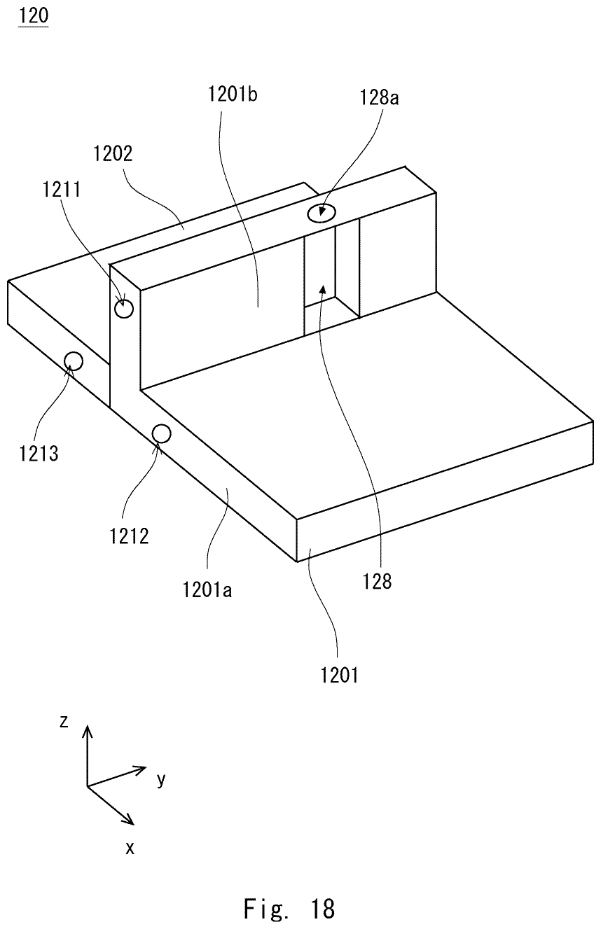

The conveyance apparatus 600 may include one or both of the above-described cooling mechanism and the displacement meters 129. Hereinafter, the configuration of the base 120 of the conveyance apparatus 600 including both the displacement meters and the cooling mechanism will be described with reference to FIGS. 16 to 18. FIG. 16 is a perspective view illustrating the base 120 to which the levitation unit 10 is fixed. FIG. 17 is a top view of the levitation unit 10. FIG. 18 is a perspective view illustrating only the configuration of the base 120. Note that description of the same contents as in FIG. 15 is omitted as appropriate.

As illustrated in FIG. 16, the reference plate 125 is fixed on the mount 126. In addition, the base 120 is fixed on the reference plate 125. The base 120 is divided into the cooling blocks 1201 and 1202. In addition, precise levitation units 111 are fixed on the cooling blocks 1201 and 1202. FIG. 16 illustrates an example in which eight precise levitation units 111 are provided, but the number of precise levitation units 111 is not particularly limited.

As illustrated in FIG. 16, a gap 132 is provided between adjacent precise levitation units 111 (levitation unit cells 131). The gap 132 is provided in the Y direction. The cooling block 1202 is provided below precise levitation units 111 on the −X side of the gap 132. The cooling block 1202 includes the cooling path 1213. The cooling block 1201 is provided below precise levitation units 111 on the +X side of the gap 132. The cooling block 1201 includes the cooling paths 1211 and 1212.

In addition, window parts 128a are provided at the cooling unit 1201b as illustrated in FIGS. 16 to 18. Detection light of each displacement meter 129 (not illustrated in FIGS. 16 to 18) passes through the corresponding window part 128a and is incident on the substrate 100 (not illustrated in FIGS. 16 to 18). Similarly, reflected light from the substrate 100 passes through the window part 128a and is incident on the displacement meter 129. The space 128 is provided below each window part 128a. As described above, the space 128 is a space for the detection light L11 of each displacement meter 129 to pass through. As illustrated in FIG. 17, the space 128 is larger than the window part 128a when viewed from top. In the cooling unit 1201b, the cooling path 1211 is provided on both sides of the space 128 in the Y direction.

With such a configuration, it is possible to measure the levitation height of the substrate 100 in the irradiation region 15a by the displacement meters 129. In addition, it is possible to reduce temperature increase due to laser beam irradiation in the irradiation region 15a. Thus, it is possible to more accurately perform levitation and execute a stable laser irradiation process.

### Exhaust Mechanism

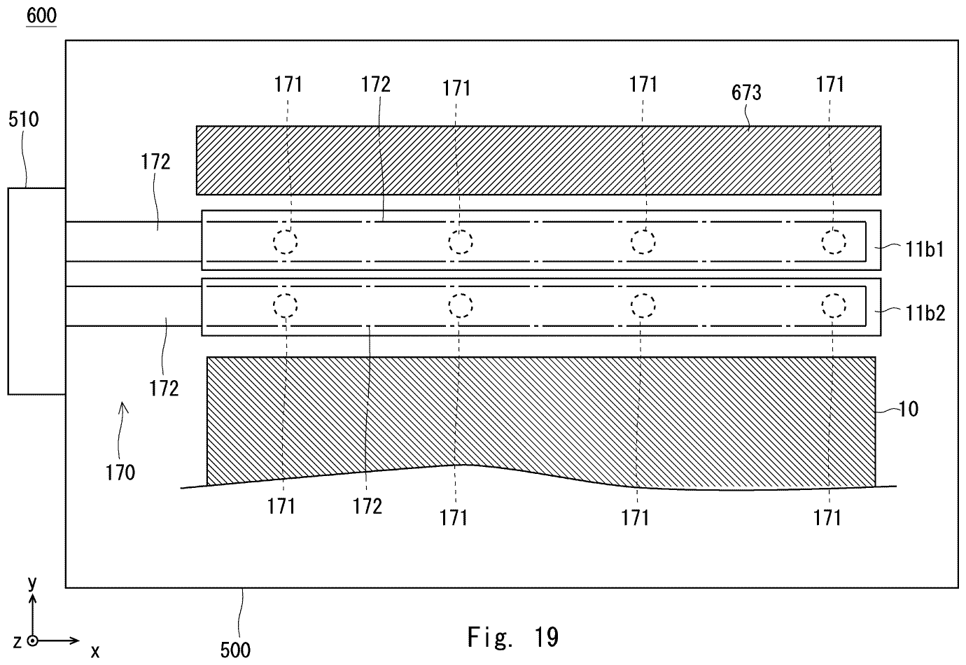

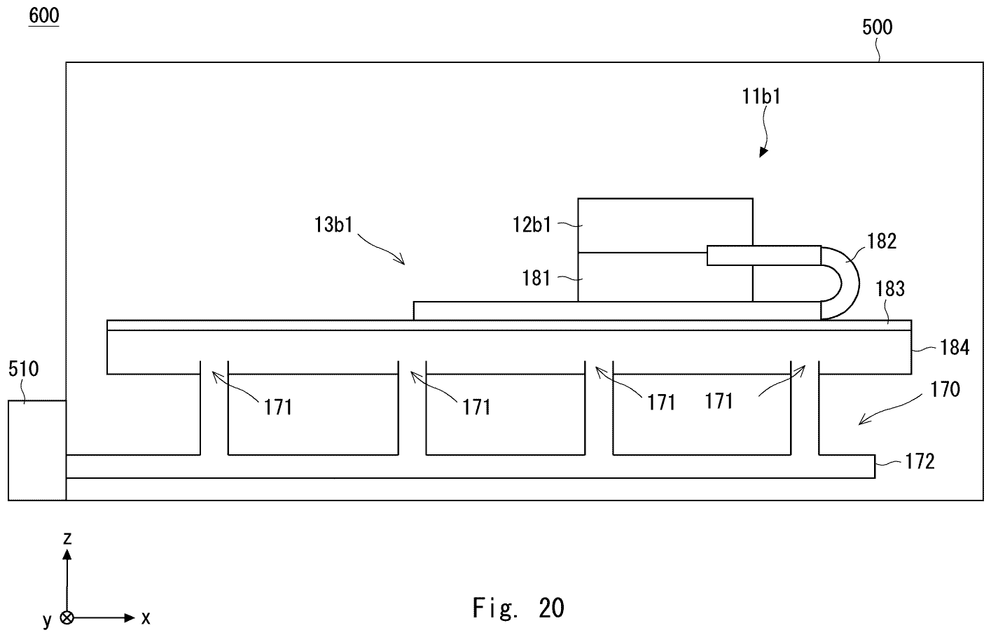

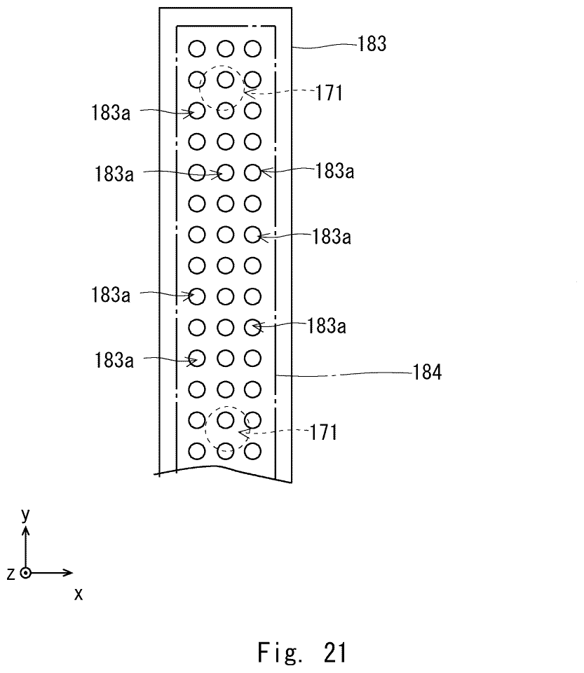

The conveyance apparatus 600 may include an exhaust mechanism configured to exhaust gas inside the chamber 500 to the outside of the chamber 500. The configuration of the exhaust mechanism will be described below with reference to FIGS. 19 to 21. FIG. 19 is a top view schematically illustrating the configuration of conveyance units and the exhaust mechanism surrounding them, and FIG. 20 is a side view thereof. FIG. 21 is a top view schematically illustrating a tray 183.

Note that, in FIG. 19, two conveyance units 11b1 and 11b2 are provided between the levitation unit 10 and the end part levitation unit 673. The conveyance units 11b1 and 11b2 correspond to the conveyance unit 11b illustrated in FIG. 4 and the like. Thus, the substrate 100 is irradiated with the laser beam 15 while being conveyed by the conveyance units 11b1 and 11b2. In FIG. 19, the direction of conveyance by the conveyance units 11b1 and 11b2 is parallel to the X direction. Accordingly, end sides of the levitation unit 10 are parallel to the X direction. FIG. 20 illustrates only the conveyance unit 11b1 and the exhaust mechanism.

The conveyance units 11b1 and 11b2 are disposed to be shifted from each other in the Y direction. The conveyance units 11b1 and 11b2 reciprocate in the X direction. The conveyance units 11b1 and 11b2 independently reciprocate. With the conveyance units 11b1 and 11b2, two substrates can be continuously conveyed in the X direction. For example, right after the first substrate 100 is conveyed in the X direction by the conveyance unit 11b1 to irradiate the first substrate 100 with the laser beam, the second substrate 100 is conveyed in the X direction by the conveyance unit 11b2. Accordingly, the two substrates 100 can be continuously irradiated with the laser beam.

The exhaust mechanism 170 is provided below the conveyance units 11b1 and 11b2. The exhaust mechanism 170 includes exhaust ports 171 and exhaust pipes 172. The exhaust ports 171 are provided directly below the conveyance units 11b1 and 11b2. The exhaust ports 171 are openings located facing upward. In this example, a plurality of exhaust ports 171 are arranged in the X direction. The exhaust ports 171 are connected to the exhaust pipes 172. With this configuration, gas in the chamber 500 flows into the exhaust pipes 172 through the exhaust ports 171. Note that four exhaust ports 171 are provided in the diagrams, but the number of exhaust ports 171 is not particularly limited.

The chamber 500 houses the levitation unit 10, the conveyance units 11b1 and 11b2, the exhaust mechanism 170, and the like. In other words, the levitation unit 10, the conveyance units 11b1 and 11b2, the exhaust mechanism 170, and the like are disposed in the chamber 500.

Each exhaust pipe 172 is connected to the exhaust unit 510 outside the chamber 500. The exhaust unit 510 generates a negative pressure in the exhaust pipe 172. Accordingly, gas in the chamber 500 is discharged from the exhaust port 171 to the outside of the chamber 500 through the exhaust pipe 172. The exhaust unit 510 may include an exhaust pump, a filter, or the like.

With this configuration, gas ejected from the levitation unit 10, the end part levitation unit 673, and the like can be discharged to the outside of the chamber 500. Accordingly, airflow in the chamber 500 can be stabilized. Thus, the substrate 100 can be accurately levitated and stably irradiated with the laser beam.

A specific example of the configuration of the conveyance unit 11b1 and the exhaust mechanism 170 will be described below with reference to FIGS. 20 and 21. The following description will be made on the conveyance unit 11b1 representing the plurality of conveyance units 11. The other conveyance units 11a, 11b2, 11c, and 11d may have the same configuration as the conveyance unit 11b1.

As illustrated in FIG. 20, the conveyance unit 11b1 includes a holding mechanism 12b1 and a moving mechanism 13b1. The holding mechanism 12b1 corresponds to the holding mechanism 12 or the holding mechanism 12b and holds an end part of the substrate 100.

The moving mechanism 13b1 corresponds to the moving mechanism 13 or the moving mechanism 13b and moves the holding mechanism 12b1 in the X direction. Accordingly, the substrate 100 moves in the X direction. The moving mechanism 13b includes a stage 181, a cable bearer 182, the tray 183, and a fixation frame 184.

The holding mechanism 12b1 is fixed on the stage 181. The stage 181 supports the holding mechanism 12b1. As described later, the stage 181 may be an upward-downward movement stage configured to move upward and downward the holding mechanism 12b1. The stage 181 is coupled to the cable bearer 182. The cable bearer 182 is provided in the X direction. With this configuration, the holding mechanism 12b1 and the stage 181 move in the X direction.

The cable bearer 182 is disposed on the tray 183. In other words, the tray 183 supports the cable bearer 182. As illustrated in FIG. 21, the tray 183 includes a plurality of through-holes 183a. The through-holes 183a penetrate through the tray 183 in the Z direction. The tray 183 is fixed to the fixation frame 184 in a frame shape. The fixation frame 184 supports a peripheral part of the tray 183. The tray 183, the fixation frame 184, the cable bearer 182, and the stage 181 are housed in the chamber 500.

The exhaust ports 171 are disposed directly below the through-holes 183a provided through the tray 183. The exhaust pipes 172 and the exhaust ports 171 are provided below the tray 183. The exhaust ports 171 are disposed directly below the tray 183. In addition, the exhaust pipes 172 provided in the X direction are disposed directly below the tray 183.

Since the exhaust ports 171 are provided below the moving mechanism 13b1 in this manner, exhaust can be achieved without affecting gas flow on the upper surface of the levitation unit 10. Thus, gas ejected from the levitation unit 10 and the like can be appropriately exhausted. Airflow in the chamber 500 can be stabilized, and the substrate 100 can be accurately levitated and stably irradiated with the laser beam. Moreover, even when particles are generated from a sliding part of the cable bearer 182, gas can be exhausted to the outside of the chamber 500 through the exhaust pipes 172. The exhaust pipes 172 are preferably disposed directly below the moving mechanism 13b1. Accordingly, space can be efficiently used.

Note that although the above description is made on the configuration of the exhaust mechanism 170 provided directly below the conveyance unit 11b1, the same exhaust mechanism 170 may be provided for the other conveyance units 11a, 11b2, 11c, and 11d, for example. No exhaust mechanism 170 may be provided for one or more of the conveyance units 11.

Note that the exhaust mechanism 170 is preferably provided for the conveyance unit 11b that conveyed the substrate 100 to irradiate the laser beam. With this configuration, airflow around the irradiation region 15a can be stabilized. Accordingly, the laser irradiation process can be reliably performed.

The conveyance method according to the present embodiment conveys the substrate by using the above-described conveyance apparatus 600. The conveyance method includes a step of holding the substrate 100 by the holding mechanism 12 and a step of conveying the substrate 100 over the levitation unit 10 by moving the holding mechanism 12 by the moving mechanism 13. Since cooling water flows through the base 120 during laser irradiation, temperature increase of the levitation unit 10 can be reduced. Accordingly, stable conveyance can be performed. Moreover, since gas is exhausted from the exhaust mechanism 170 during laser irradiation, stable conveyance can be performed.

### Upward-Downward Operation of Holding Mechanism 12

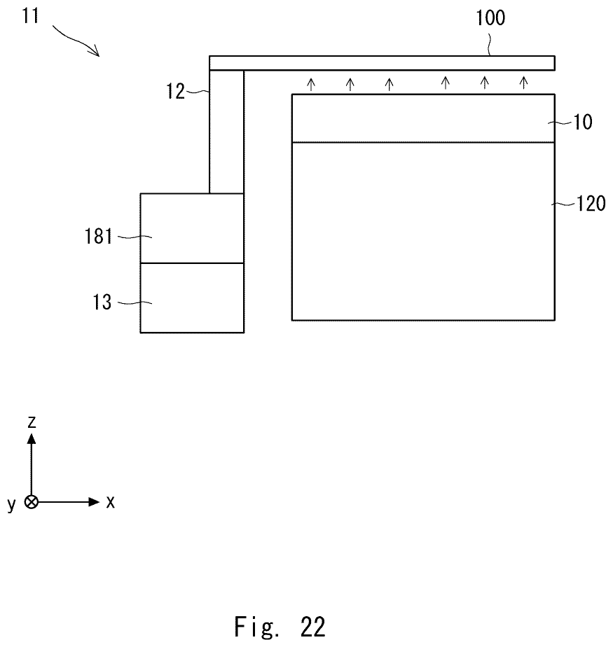

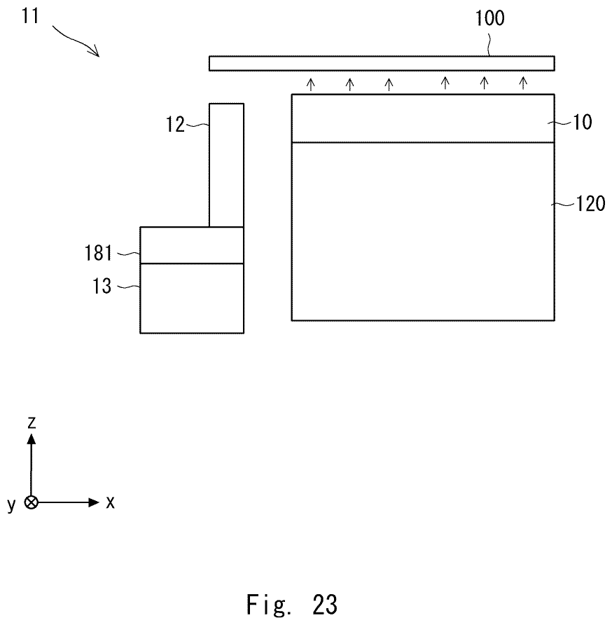

Upward-downward operation of the holding mechanism 12 will be described next with reference to FIGS. 22 and 23. FIGS. 22 and 23 are side views schematically illustrating a conveyance unit 11 and its surrounding components. FIG. 22 illustrates a state in which the holding mechanism 12 is moved up (moved-up position), and FIG. 23 illustrates a state in which the holding mechanism 12 is moved down (also referred to as a moved-down position). FIGS. 22 and 23 illustrate the conveyance unit 11 having a conveyance direction in the y direction.

The stage 181 supports the holding mechanism 12. The stage 181 is an upward-downward movement stage and moves the holding mechanism 12 in the Z direction. The stage 181 includes an actuator such as a motor, a guide mechanism, and the like. The height of the upper surface (holding surface) of the holding mechanism 12 can be changed by drive of the actuator of the stage 181.

As illustrated in FIG. 4, a plurality of conveyance units 11 are provided around the levitation unit 10. The plurality of conveyance units 11 convey the substrate 100 to orbit. Specifically, the substrate 100 is handed over between the conveyance unit 11b or 11d for moving in the X direction and the conveyance unit 11a or 11c for moving in the Y direction. For example, in the state illustrated in FIG. 6, the substrate 100 is handed over from the conveyance unit 11a to the conveyance unit 11b. In this case, the conveyance unit 11a is the hand-over source, and the conveyance unit 11b is the hand-over destination.

In the conveyance unit 11 at the hand-over destination, the upper surface (holding surface) of the holding mechanism 12 is higher than the upper surface (levitation surface) of the levitation unit 10 as illustrated in FIG. 22. In other words, the conveyance unit 11 is moved up to the moved-up position by the stage 181. After the holding mechanism 12 is moved to the height of the moved-up position by the stage 181, the substrate 100 is vacuum-adsorbed.

In the conveyance unit 11 at the hand-over source, the upper surface (holding surface) of the holding mechanism 12 is lower than the upper surface (levitation surface) of the levitation unit 10 as illustrated in FIG. 23. In other words, the conveyance unit 11 is moved down to the moved-down position by the stage 181. After vacuum adsorption is canceled by the holding mechanism 12, the conveyance unit is moved to the height of the moved-down position by the stage 181.

In this manner, the conveyance unit 11 moves the holding mechanism 12 to a position lower than the upper surface of the levitation unit 10 when the substrate 100 is not vacuum-adsorbed. Accordingly, the substrate 100 can be appropriately handed over between two conveyance units 11.

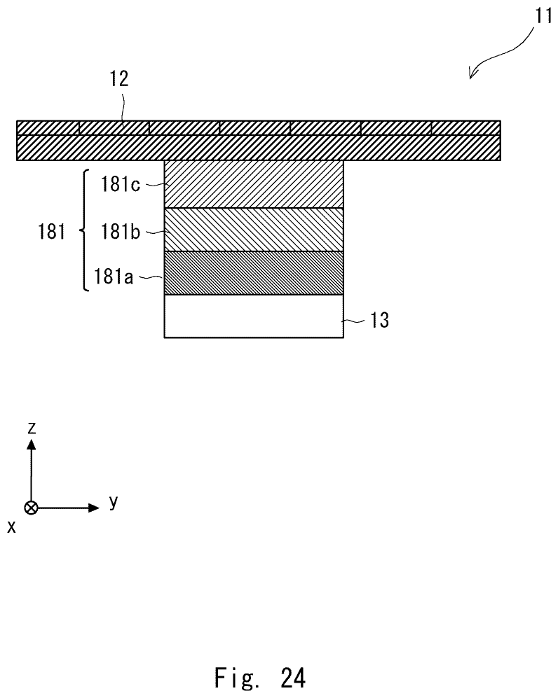

The configuration of the stage 181 provided with the holding mechanism 12 will be described next with reference to FIG. 24. FIG. 24 is a side view schematically illustrating the configuration of the holding mechanism 12 and the stage 181. Note that FIG. 24 illustrates the holding mechanism 12 of a conveyance unit 11 having a conveyance direction in the y direction.

The stage 181 includes a lower stage 181a, a Z-axis mechanism 181b, and an upper stage 181c. The lower stage 181a, the Z-axis mechanism 181b, and the upper stage 181c are disposed in the stated order from the lower side. Accordingly, the Z-axis mechanism 181b is disposed between the upper stage 181c and the lower stage 181a. The upper stage 181c supports the holding mechanism 12. The lower stage 181a is supported by the moving mechanism 13. For example, the lower stage 181a is attached to a slider of a linear motor.

The Z-axis mechanism 181b is an upward-downward mechanism including a guide extending in the Z direction and an actuator. The Z-axis mechanism 181b is a wedge-shaped upward-downward mechanism including a linear guideway. The Z-axis mechanism 181b supports the upper stage 181c in a manner movable upward and downward. Accordingly, the Z-axis mechanism 181b can move the upper stage 181c upward and downward. Note that the holding mechanism 12 may be divided into a plurality of parts and hold the substrate 100 by adsorption.

The conveyance method according to the present embodiment conveys the substrate by using the above-described conveyance apparatus. The conveyance method includes a step of holding the substrate by a holding mechanism and a step of conveying the substrate over the levitation unit by moving the holding mechanism by the moving mechanism. The levitation height of the substrate is measured by a displacement meter.

### Organic Light-Emitting Diode Display

A semiconductor apparatus including the above-described poly-silicon film is preferable for a thin film transistor (TFT) array substrate for electroluminescence display. Specifically, the poly-silicon film is used as a semiconductor layer including the source region, the channel region, and the drain region of a TFT.

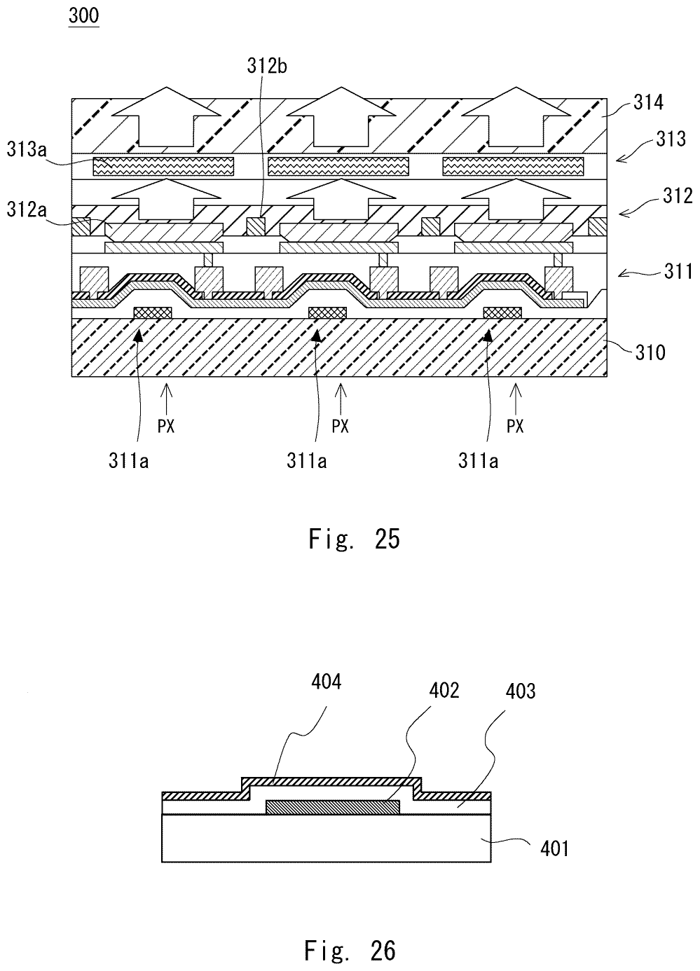

A configuration in which a semiconductor apparatus according to the present embodiment is applied to organic light-emitting diode display will be described below. FIG. 25 is a cross-sectional view illustrating pixel circuits of the organic light-emitting diode display in a simplified manner. This organic light-emitting diode display 300 illustrated in FIG. 25 is an active matrix display apparatus in which a TFT is disposed at each pixel PX.

The organic light-emitting diode display 300 includes a substrate 310, a TFT layer 311, an organic layer 312, a color filter layer 313, and a sealing substrate 314. A top-emission organic light-emitting diode display in which the sealing substrate 314 side is a viewing side is illustrated in FIG. 25. Note that the following description presents a configuration example of the organic light- emitting diode display, and the present embodiment is not limited to configurations described below. For example, the semiconductor apparatus according to the present embodiment may be used for a bottom-emission organic light-emitting diode display.

The substrate 310 is a glass substrate or a metal substrate. The TFT layer 311 is provided on the substrate 310. The TFT layer 311 includes a TFT 311a disposed at each pixel PX. The TFT layer 311 also includes a wire (not illustrated) connected to the TFT 311a, and the like. The TFT 311a, the wire, and the like constitute a pixel circuit.

The organic layer 312 is provided on the TFT layer 311. The organic layer 312 includes an organic electroluminescence light-emitting element 312a disposed for each pixel PX. The organic layer 312 is also provided with a partition 312b for separating the organic electroluminescence light-emitting elements 312a of each pair of pixels PX.

The color filter layer 313 is provided on the organic layer 312. The color filter layer 313 is provided with color filters 313a for performing color display. Specifically, a resin layer colored in red (R), green (G), or blue (B) is provided as the color filter 313a at each pixel PX.

The sealing substrate 314 is provided on the color filter layer 313. The sealing substrate 314 is a transparent substrate such as a glass substrate and provided to prevent degradation of the organic electroluminescence light-emitting elements of the organic layer 312.

Current that flows to each organic electroluminescence light-emitting elements 312a of the organic layer 312 changes with a display signal supplied to the pixel circuit. Thus, the amount of light emission at each pixel PX can be controlled by supplying a display signal in accordance with a display image to the pixel PX. Accordingly, a desired image can be displayed.

In an active matrix display apparatus such as an organic light-emitting diode display, each pixel PX is provided with one or more TFTs (for example, switching TFT or drive TFT). In addition, a semiconductor layer including a source region, a channel region, and a drain region is provided at each TFT of each pixel PX. The poly-silicon film according to the present embodiment is preferable for the semiconductor layer of each TFT. Specifically, in-plane variance of TFT characteristics can be reduced by using, as the semiconductor layer of a TFT array substrate, a poly-silicon film manufactured by the above-described manufacturing method. Thus, a display apparatus with excellent display characteristics can be manufactured at high productivity.

### Semiconductor Apparatus Manufacturing Method

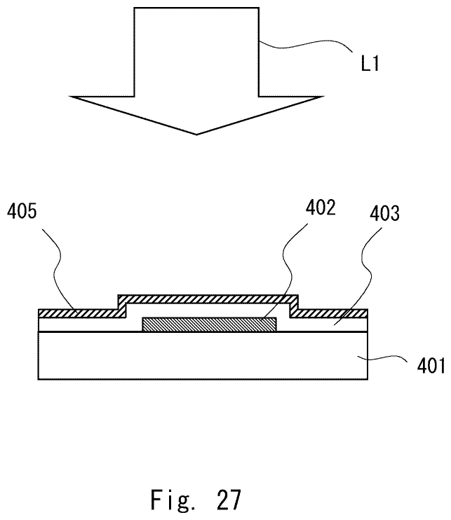

A semiconductor apparatus manufacturing method using the laser irradiation apparatus according to the present embodiment is preferable for manufacturing of a TFT array substrate. A method of manufacturing a semiconductor apparatus including a TFT will be described below with reference to FIGS. 26 and 27. FIGS. 26 and 27 are process cross-sectional views illustrating a semiconductor apparatus manufacturing process. The following description will be made on a method of manufacturing a semiconductor apparatus including an inverted staggered TFT. In FIGS. 26 and 27, a poly-silicon film formation process in the semiconductor manufacturing method is illustrated. Note that well-known methods can be used for other manufacturing processes, and thus description thereof is omitted.

As illustrated in FIG. 26, a gate electrode 402 is formed on a glass substrate 401. A gate insulating film 403 is formed on the gate electrode 402. An amorphous silicon film 404 is formed on the gate insulating film 403. The amorphous silicon film 404 is disposed to overlap the gate electrode 402 with the gate insulating film 403 interposed therebetween. For example, the gate insulating film 403 and the amorphous silicon film 404 are continuously deposited by a chemical vapor deposition (CVD) method.

Then, the glass substrate 401 on which the amorphous silicon film 404 is formed is conveyed to the above-described conveyance apparatus 600. A poly-silicon film 405 is formed by irradiating the amorphous silicon film 404 with a laser beam L1 as illustrated in FIG. 27. Specifically, the amorphous silicon film 404 is crystallized by the laser irradiation apparatus 1 illustrated in FIG. 1 and the like. Accordingly, the poly-silicon film 405 in which silicon is crystallized is formed on the gate insulating film 403. The poly-silicon film 405 corresponds to the above-described poly-silicon film. Irradiation with the laser beam L1 is performed while the conveyance apparatus 600 conveys the glass substrate 401. Accordingly, the amorphous silicon film 404 is annealed and converted into the poly-silicon film 405.

Moreover, in the above description, the laser anneal apparatus according to the present embodiment irradiates an amorphous silicon film with a laser beam to form a poly-silicon film but may configured to irradiate an amorphous silicon film with a laser beam to form a microcrystalline silicon film. Further, a laser beam that performs anneal is not limited to a Nd:YAG laser. The method according to the present embodiment is also applicable to a laser anneal apparatus that crystallizes a thin film other than a silicon film. Specifically, the method according to the present embodiment is applicable to any laser anneal apparatus that irradiates an amorphous film with a laser beam to form a crystallized film. With the laser anneal apparatus according to the present embodiment, a substrate with a crystallized film can be appropriately reformed.

The semiconductor apparatus manufacturing method according to the present embodiment may include steps (s1) to (s2) described below.

(s1) step of forming an amorphous film on a substrate.

(s2) step of annealing the amorphous film by irradiating the substrate with a linear laser beam while conveying the substrate by using the conveyance apparatus so that the amorphous film is crystallized to form a crystallized film.

At step (s2), the above-described conveyance apparatus 600 conveys the substrate 100. The conveyance apparatus 600 does not necessarily need to include all above-described components.

Note that the present invention is not limited to the above-described embodiment but can be modified as appropriate without departing from the scope thereof.

### REFERENCE SIGNS LIST

1 LASER IRRADIATION APPARATUS
10 LEVITATION UNIT
11 CONVEYANCE UNIT
12 HOLDING MECHANISM
13 MOVING MECHANISM
14 LASER IRRADIATION UNIT
15 LASER BEAM
15a IRRADIATION REGION
31 PRECISE LEVITATION REGION
32 SEMI-PRECISE LEVITATION REGION
33 ROUGH LEVITATION REGION
60a FIRST REGION
60b SECOND REGION
60c THIRD REGION
60d FOURTH REGION
60e PROCESS REGION
60f PASSING REGION
670 to 676 END PART LEVITATION UNIT
68 ROTARY MECHANISM
69a, 69b ALIGNMENT MECHANISM
100 SUBSTRATE
111 PRECISE LEVITATION UNIT
112 SEMI-PRECISE LEVITATION UNIT
113 ROUGH LEVITATION UNIT
120 BASE
125 REFERENCE PLATE
126 MOUNT
128 SPACE
129 DISPLACEMENT METER
131 LEVITATION UNIT CELL
132 GAP
300 ORGANIC LIGHT-EMITTING DIODE DISPLAY
310 SUBSTRATE
311 TFT LAYER
311a TFT
312 ORGANIC LAYER
312a ORGANIC ELECTROLUMINESCENCE LIGHT-EMITTING ELEMENT
312b PARTITION
313 COLOR FILTER LAYER
313a COLOR FILTER (CF)
314 SEALING SUBSTRATE
401 GLASS SUBSTRATE
402 GATE ELECTRODE
403 GATE INSULATING FILM
404 AMORPHOUS SILICON FILM
405 POLY-SILICON FILM
500 CHAMBER
510 EXHAUST UNIT
671 to 676 END PART LEVITATION UNIT
PX PIXEL

1. A conveyance apparatus configured to convey a substrate to irradiate the substrate with a linear laser beam, the conveyance apparatus comprising:
a levitation unit including a plurality of levitation unit cells arranged with gaps in between, the levitation unit being configured to levitate the substrate over an upper surface of the levitation unit;
a holding mechanism configured to hold the substrate over the levitation unit;
a moving mechanism configured to move the holding mechanism in a conveyance direction tilted from a line direction of the laser beam when viewed from top to change an irradiation position of the laser beam on the substrate;
a base supporting the levitation unit cells; and
a displacement meter provided in a gap directly below an irradiation region of the laser beam to detect height of the substrate.

2. The conveyance apparatus according to claim 1, wherein
the conveyance apparatus includes a plurality of the displacement meters, and
the plurality of displacement meters are arranged in the line direction of the laser beam.

3. The conveyance apparatus according to claim 1, wherein
the base includes a cooling unit disposed in the gap in the irradiation region of the laser beam, and
the cooling unit includes a cooling path provided in the line direction of the laser beam.

4. The conveyance apparatus according to claim 3, wherein the base is provided with a space for detection light of the displacement meter to pass through or a space for disposing the displacement meter.

5. A conveyance apparatus configured to convey a substrate to irradiate the substrate with a linear laser beam, the conveyance apparatus comprising:
a levitation unit including a plurality of levitation unit cells arranged with gaps in between, the levitation unit being configured to levitate the substrate over an upper surface of the levitation unit;
a holding mechanism configured to hold the substrate over the levitation unit;
a moving mechanism configured to move the holding mechanism in a conveyance direction tilted from a line direction of the laser beam when viewed from top to change an irradiation position of the laser beam on the substrate;
a base supporting the levitation unit cells; and
a cooling unit provided at the base, disposed in the gap in the irradiation region of the laser beam, and including a cooling path disposed in the line direction of the laser beam.

6. The conveyance apparatus according to claim 1, comprising:
a tray provided with a through-hole and supporting the moving mechanism;
a chamber housing the levitation unit cell, the holding mechanism, the moving mechanism, and the base; and
an exhaust pipe including an exhaust port disposed below the tray, the exhaust pipe being connected to outside of the chamber.

7. A conveyance apparatus configured to convey a substrate to irradiate the substrate with a linear laser beam, the conveyance apparatus comprising:
a levitation unit including a plurality of levitation unit cells arranged with gaps in between, the levitation unit being configured to levitate the substrate over an upper surface of the levitation unit;
a holding mechanism configured to hold the substrate over the levitation unit;
a moving mechanism configured to move the holding mechanism in a conveyance direction tilted from a line direction of the laser beam when viewed from top to change an irradiation position of the laser beam on the substrate;
a tray provided with a through-hole and supporting the moving mechanism;
a chamber housing the levitation unit, the holding mechanism, the moving mechanism, and the tray; and
an exhaust pipe including an exhaust port disposed below the tray, the exhaust pipe being connected to outside of the chamber.

8. A conveyance method of conveying a substrate by using a conveyance apparatus to irradiate the substrate with a linear laser beam, wherein
the conveyance apparatus includes
a levitation unit including a plurality of levitation unit cells arranged with gaps in between, the levitation unit being configured to levitate the substrate over an upper surface of the levitation unit,
a base supporting the levitation unit cells, and
a displacement meter provided in a gap directly below an irradiation region of the laser beam to detect height of the substrate, and
the conveyance method includes
(A1) step of holding the substrate by a holding mechanism,
(A2) step of conveying the substrate over the levitation unit by moving the holding mechanism by a moving mechanism, and
(A3) step of measuring, by the displacement meter, levitation height of the substrate being conveyed.

9. The conveyance method according to claim 8, wherein
the conveyance apparatus includes a plurality of the displacement meters, and
the plurality of displacement meters are arranged in the line direction of the laser beam.

10. The conveyance method according to claim 8, wherein
the base includes a cooling unit disposed in the gap in the irradiation region of the laser beam, and
the cooling unit includes a cooling path provided in the line direction of the laser beam.

11. The conveyance method according to claim 10, wherein the base is provided with a space for detection light of the displacement meter to pass through or a space for disposing the displacement meter.

12. (canceled)

13. The conveyance method according to claim 8, wherein the conveyance apparatus includes
a tray provided with a through-hole and supporting the moving mechanism,
a chamber housing the levitation unit cell, the holding mechanism, the moving mechanism, and the base, and
an exhaust pipe including an exhaust port disposed below the tray, the exhaust pipe being connected to outside of the chamber.

14. (canceled)

15. A semiconductor apparatus manufacturing method comprising:
(sa1) step of forming an amorphous film on a substrate; and
(sa2) step of annealing the amorphous film by irradiating the substrate with a linear laser beam while conveying the substrate by using a conveyance apparatus so that the amorphous film is crystallized to form a crystallized film,
wherein the conveyance apparatus includes
a levitation unit including a plurality of levitation unit cells arranged with gaps in between, the levitation unit being configured to levitate the substrate over an upper surface of the levitation unit,
a holding mechanism configured to hold the substrate over the levitation unit,
a moving mechanism configured to move the holding mechanism in a conveyance direction tilted from a line direction of the laser beam when viewed from top to change an irradiation position of the laser beam on the substrate,
a base supporting the levitation unit cells, and
a displacement meter provided in a gap directly below an irradiation region of the laser beam to detect height of the substrate.

16. The semiconductor apparatus manufacturing method according to claim 15, wherein
the conveyance apparatus includes a plurality of the displacement meters, and
the plurality of displacement meters are arranged in the line direction of the laser beam.

17. The semiconductor apparatus manufacturing method according to claim 15, wherein
the base includes a cooling unit disposed in the gap in the irradiation region of the laser beam, and
the cooling unit includes a cooling path provided in the line direction of the laser beam.

18. The semiconductor apparatus manufacturing method according to claim 16, wherein the base is provided with a space for detection light of the displacement meter to pass through or a space for disposing the displacement meter.

19. (canceled)

20. The semiconductor apparatus manufacturing method according to claim 15, the conveyance apparatus comprising:
a tray provided with a through-hole and supporting the moving mechanism;
a chamber housing the levitation unit cell, the holding mechanism, the moving mechanism, and the base; and
an exhaust pipe including an exhaust port disposed below the tray, the exhaust pipe being connected to outside of the chamber.

21. (canceled)
